(19) United States
(12) Patent Application Publication
(10) Pub. No.: US 2026/0146156 A1
(43) Pub. Date: May 28, 2026

(54) RESIN COMPOSITION AND ARTICLE MADE THEREFROM

(71) Applicant: Elite Electronic Material (KunShan) Co., Ltd., Kunshan City (CN)

(72) Inventors: Yan ZHANG, Kunshan City (CN); Rongtao WANG, Kunshan City (CN); Zhaopeng LUO, Kunshan City (CN); Xingxing YAO, Kunshan City (CN); Wentao XUE, Kunshan City (CN); Diya LIU, Kunshan City (CN)

(21) Appl. No.: 19/014,503

(22) Filed: Jan. 9, 2025

(30) Foreign Application Priority Data
Nov. 28, 2024 (CN) 2024117196060

(51) Int. Cl. C08L 71/12; C08K 5/01

(52) U.S. Cl. CPC C08L 71/12; C08K 5/01

(57) ABSTRACT

A resin composition includes 100 parts by weight of an unsaturated C═C double bond-containing polyphenylene ether resin; 5 parts by weight to 100 parts by weight of a compound of Formula (1), a compound of Formula (2), an oligomer of the compound of Formula (1), an oligomer of the compound of Formula (2) or a combination thereof; and 5 parts by weight to 100 parts by weight of a benzocyclobutene-modified polyolefin. Moreover, also provided is an article made from the resin composition, including a prepreg, a resin film, a laminate or a printed circuit board, and improvements in various properties can be achieved including post-plating copper foil peeling strength uniformity, Z-axis coefficient of thermal expansion and storage modulus variation rate.

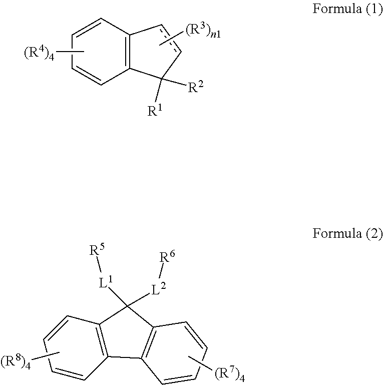

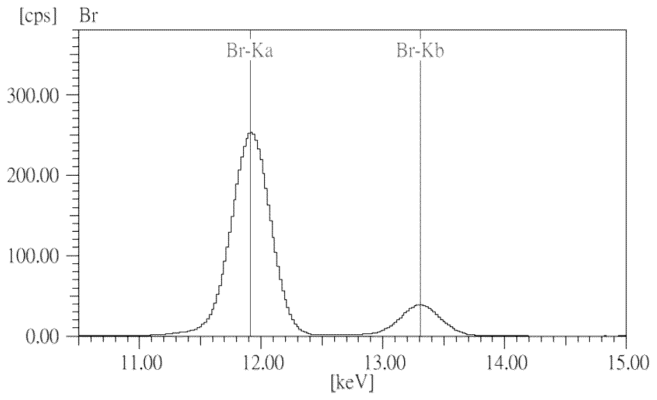

### CROSS-REFERENCE TO RELATED APPLICATION

This application claims the priority benefits of China Patent Application No. 2024117196060, filed on Nov. 28, 2024. The entirety of the above-mentioned patent application is hereby incorporated by reference herein and made a part of this specification.

### BACKGROUND

### 1. Field of the Disclosure

The present disclosure mainly relates to a resin composition and an article made therefrom, more particularly to a resin composition useful for preparing a prepreg, a resin film, a laminate (e.g., a copper-clad laminate) and a printed circuit board, and an article made therefrom.

### 2. Description of Related Art

In recent years, with the development of 5G, electronic products have tended to process information at higher speed and larger capacity. In addition, in order to adapt to market demand, electronic products are becoming increasingly thinner, lighter and shorter. Therefore, the density and complexity of printed circuit boards are gradually increasing, which also presents higher demands in the performance of printed circuit board materials.

The main chain of polyphenylene ether resins contains a large number of benzene rings and ether bonds. They have good mechanical properties and better dielectric properties, and are ideal raw materials for printed circuit boards. However, the articles currently on the market made from the resin composition containing polyphenylene ether resin still have at least one or more disadvantages including poor post-plating copper foil peeling strength uniformity, presence of microvoids in the laminate, high Z-axis coefficient of thermal expansion and high storage modulus variation rate.

### SUMMARY

To overcome the problems facing prior arts, particularly one or more of the above-mentioned technical problems of properties for conventional materials, it is a primary object of the present disclosure to provide a resin composition and an article made therefrom which may overcome at least one of the above-mentioned technical problems. More specifically, the primary object of the present disclosure is to provide a resin composition, and an article made therefrom has one, more or all of the properties including better post-plating copper foil peeling strength uniformity, lower Z-axis coefficient of thermal expansion, lower storage modulus variation rate and fewer microvoids in the laminate.

To achieve the above-mentioned objects, the present disclosure provides a resin composition, comprising: (A) 100 parts by weight of an unsaturated C═C double bond-containing polyphenylene ether resin; (B) 5 parts by weight to 100 parts by weight of a compound of Formula (1), a compound of Formula (2), an oligomer of the compound of Formula (1), an oligomer of the compound of Formula (2) or a combination thereof; and (C) 5 parts by weight to 100 parts by weight of a benzocyclobutene-modified polyolefin;

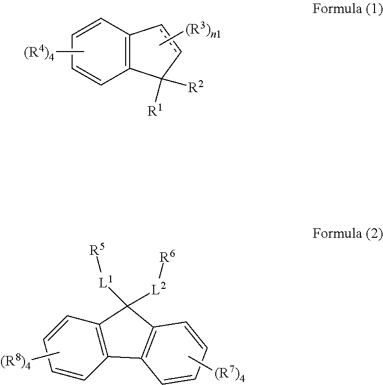

in Formula (1), R¹, R² and R³ are each independently selected from a hydrogen atom, a C₁ to C₅ alkyl group, a vinylphenyl group, a vinylbenzyl group, an allylphenyl group and an allylbenzyl group, and at least one of R¹, R² and R³ is a vinylphenyl group, a vinylbenzyl group, an allylphenyl group or an allylbenzyl group; R⁴ is each independently selected from a hydrogen atom and a C₁ to C₅ alkyl group; [symbol] represents a C—C single bond or a C═C double bond; when [symbol] represents a C—C single bond, n1 is 4, and when [symbol] represents a C═C double bond, n1 is 2;
in Formula (2), L¹ and L² are each independently selected from a C₁ to C₅ alkylene group and a C₆ to C₁₂ arylene group; R⁵ and R⁶ are each independently selected from a hydrogen atom, a C₁ to C₅ alkyl group, a vinylphenyl group, a vinylbenzyl group, an allylphenyl group and an allylbenzyl group, and at least one of R⁵ and R⁶ is a vinylphenyl group, a vinylbenzyl group, an allylphenyl group or an allylbenzyl group; and R⁷ and R⁸ are each independently selected from a hydrogen atom and a C₁ to C₅ alkyl group.

For example, in one embodiment, the compound of Formula (1), the compound of Formula (2), the oligomer of the compound of Formula (1), the oligomer of the compound of Formula (2) or a combination thereof is 5 parts by weight to 75 parts by weight.

For example, in one embodiment, the benzocyclobutene-modified polyolefin is 5 parts by weight to 80 parts by weight.

For example, in one embodiment, the unsaturated C═C double bond-containing polyphenylene ether resin comprises a vinylbenzyl group-containing polyphenylene ether resin, a (meth)acryloyl group-containing polyphenylene ether resin, a vinyl group-containing polyphenylene ether resin, an allyl group-containing polyphenylene ether resin or a combination thereof.

For example, in one embodiment, the compound of Formula (1) comprises a compound of Formula (1-1), a compound of Formula (1-2), a compound of Formula (1-3), a compound of Formula (1-4) or a combination thereof; the compound of Formula (2) comprises a compound of Formula (2-1), a compound of Formula (2-2), a compound of Formula (2-3) or a combination thereof:

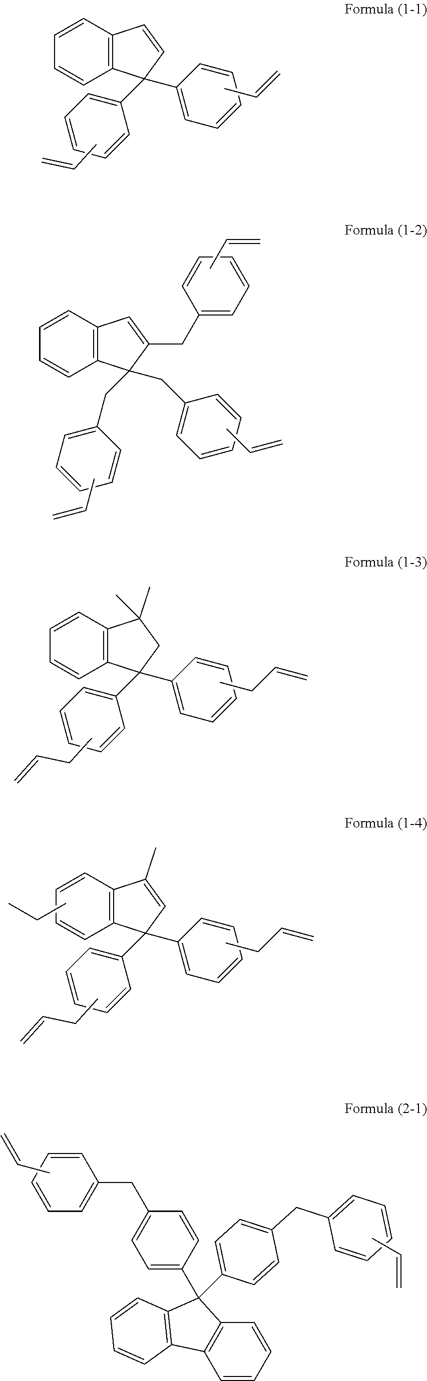

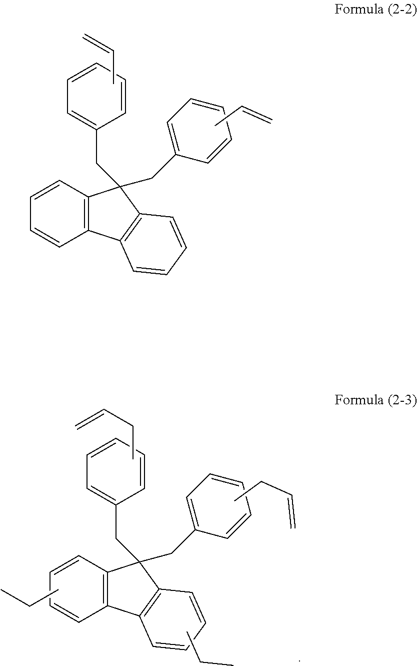

For example, in one embodiment, the benzocyclobutene-modified polyolefin comprises a benzocyclobutene-modified polyolefin containing a heteroatom, a benzocyclobutene-modified polyolefin not containing a heteroatom or a combination thereof.

For example, in one embodiment, the benzocyclobutene-modified polyolefin comprises a benzocyclobutene-modified polyolefin containing a heteroatom and a benzocyclobutene-modified polyolefin not containing a heteroatom at a weight ratio of 2:1 to 1:9.

For example, in one embodiment, the benzocyclobutene-modified polyolefin comprises a benzocyclobutene-modified polybutadiene, a benzocyclobutene-modified polyisoprene, a benzocyclobutene-modified product of styrene-butadiene copolymer, a benzocyclobutene-modified product of styrene-isoprene copolymer, a benzocyclobutene-modified product of styrene-butadiene-divinylbenzene polymer, a benzocyclobutene-modified product of styrene-ethylene-divinylbenzene polymer, a benzocyclobutene-modified product of styrene-ethylstyrene-divinylbenzene polymer, a benzocyclobutene-modified product of maleic anhydride-adducted polybutadiene, a benzocyclobutene-modified product of maleic anhydride-adducted polyisoprene, a benzocyclobutene-modified product of maleic anhydride-adducted styrene-butadiene copolymer, a benzocyclobutene-modified product of maleic anhydride-adducted styrene-isoprene copolymer, a benzocyclobutene-modified product of vinyl-polybutadiene-urethane polymer, a benzocyclobutene-modified product of silane-containing styrene-butadiene copolymer, a benzocyclobutene-modified product of acryloyl-terminated polybutadiene, a benzocyclobutene-modified product of epoxy-containing polybutadiene or a combination thereof.

For example, in one embodiment, the resin composition further comprises a polyolefin different from the benzocyclobutene-modified polyolefin, an organic silicone resin, a benzoxazine resin, an epoxy resin, a polyester resin, a phenol resin, an amine curing agent, a polyamide, a polyimide, a maleimide resin, a cyanate ester resin, a maleimide triazine resin or a combination thereof.

For example, in one embodiment, the resin composition further comprises curing accelerator, polymerization inhibitor, flame retardant, inorganic filler, surface treating agent, coloring agent, toughening agent, solvent or a combination thereof.

In another aspect, the present disclosure also provides an article made from the aforesaid resin composition. For example, in one embodiment, the article comprises a prepreg, a resin film, a laminate or a printed circuit board.

For example, in one embodiment, the article described above has at least one, more or all of the following properties:
a difference in post-plating copper foil peeling strength between peripheral area and central area as measured and calculated by reference to IPC-TM-650 2.4.8 of less than or equal to 0.34 lb/in;
a Z-axis coefficient of thermal expansion as measured by reference to IPC-TM-650 2.4.24.5 of less than or equal to 43 ppm/° C.;
a storage modulus variation rate as measured and calculated by reference to IPC-TM-650 2.4.24.4 of less than or equal to 40%; and
absence of microvoids on surface of laminate section as measured by using focused ion beam processing and imaging technology.

### BRIEF DESCRIPTION OF THE DRAWINGS

The sole FIGURE illustrates the X-ray fluorescence spectrum of the product made from Preparation Example 1.

### DESCRIPTION OF THE EMBODIMENTS

To enable those skilled in the art to further appreciate the features and effects of the present disclosure, words and terms contained in the specification and appended claims are described and defined. Unless otherwise defined, all technical and scientific terms used herein have the same meaning as commonly understood by those of ordinary skill in the art to which this disclosure pertains. In the case of conflict, the present document and definitions contained herein will control.

While some theories or mechanisms may be proposed herein, the present disclosure is not bound by any theories or mechanisms described regardless of whether they are right or wrong, as long as the embodiments can be implemented according to the present disclosure.

As used herein, “a,” “an” or any similar expression is employed to describe components and features of the present disclosure. This is done merely for convenience and to give a general sense of the scope of the present disclosure. Accordingly, this description should be read to include one or at least one and the singular also includes the plural unless it is obvious to mean otherwise.

As used herein, the term “encompasses,” “encompassing,” “comprises,” “comprising,” “includes,” “including,” “has,” “having” or any other variant thereof is construed as an open-ended transitional phrase intended to cover a non-exclusive inclusion. For example, a composition comprising a list of elements or an article made therefrom encompasses any one or any type of the listed elements and is not necessarily limited to only those elements listed herein, but may also include other elements not expressly listed or inherent to such composition or article. Further, unless expressly stated to the contrary, the term “or” refers to an inclusive or and not to an exclusive or. For example, a condition “A or B” is satisfied by any one of the following: A is true (or present) and B is false (or not present), A is false (or not present) and B is true (or present), and both A and B are true (or present). In addition, whenever open-ended transitional phrases are used, such as “encompasses,” “encompassing,” “comprises,” “comprising,” “includes,” “including,” “has,” “having” or any other variant thereof, it is understood that close-ended transitional phrases such as “consisting of,” “composed by” and “remainder being” and partially open-ended transitional phrases such as “consisting essentially of,” “primarily consisting of,” “mainly consisting of,” “primarily containing,” “composed essentially of,” “essentially having,” etc. are also disclosed and included.

As used herein, “or a combination thereof” means “or any combination thereof” encompasses any combination of two or more of the listed elements, and “any” means “any one”, vice versa. For example, a composition or an article made therefrom “includes A, B, C or a combination thereof” or a composition or an article made therefrom “includes any one of A, B and C or a combination thereof” is construed to encompass the following situations: A is true (or present), and B and C are false (or not present); B is true (or present), and A and C are false (or not present); C is true (or present), and A and B are false (or not present); A and B are true (or present), and C is false (or not present); A and C are true (or present), and B is false (or not present); B and C are true (or present), and A is false (or not present); A, B and C are all true (or present), and other elements not expressly listed but inherent to such composition or article.

As used herein, the term “and” or any other variant thereof is used to connect parallel sentence components, and there is no distinction between the front and rear components. The meaning of the parallel sentence components does not change in the grammatical sense after the position is exchanged.

In this disclosure, features and conditions such as values, numbers, contents, amounts or concentrations are presented as a numerical range or a percentage range merely for convenience and brevity. Therefore, a numerical range or a percentage range should be interpreted as encompassing and specifically disclosing all possible subranges and individual numerals or values therein, including integers and fractions, particularly all integers therein. For example, a range of “1.0 to 8.0” or “between 1.0 and 8.0” should be understood as explicitly disclosing all subranges such as 1.0 to 8.0, 1.0 to 7.0, 2.0 to 8.0, 2.0 to 6.0, 3.0 to 6.0, 4.0 to 8.0, 3.0 to 8.0 and so on and encompassing the endpoint values, particularly subranges defined by integers, as well as disclosing all individual values in the range such as 1.0, 2.0, 3.0, 4.0, 5.0, 6.0, 7.0 and 8.0. Unless otherwise defined, the aforesaid interpretation rule should be applied throughout the present disclosure regardless of broadness of the scope.

Whenever amount, concentration or other numeral or parameter is expressed as a range, a preferred range or a series of upper and lower limits, it is understood that all ranges defined by any pair of the upper limit or preferred value and the lower limit or preferred value are specifically disclosed, regardless whether these ranges are explicitly described or not. In addition, unless otherwise defined, whenever a range is mentioned, the range should be interpreted as inclusive of the endpoints and every integers and fractions in the range.

Given the intended purposes and advantages of this disclosure are achieved, numerals or figures have the precision of their significant digits.

As used herein, a Markush group or a list of items is used to describe examples or embodiments of the present disclosure. A skilled artisan will appreciate that all subgroups of members or items and individual members or items of the Markush group or list can also be used to describe the present disclosure. For example, when X is described as being “selected from a group consisting of X₁, X₂ and X₃,” it is intended to disclose the situations of X is X₁ and X is X₁ and/or X₂ and/or X₃. In addition, when a Markush group or a list of items is used to describe examples or embodiments of the present disclosure, a skilled artisan will understand that any subgroup or any combination of the members or items in the Markush group or list may also be used to describe the present disclosure. Therefore, for example, when X is described as being “selected from a group consisting of X₁, X₂ and X₃” and Y is described as being “selected from a group consisting of Y₁, Y₂ and Y₃,” the disclosure encompasses any combination of X is X₁ and/or X₂ and/or X₃ and Y is Y₁ and/or Y₂ and/or Y₃.

Unless otherwise specified, according to the present disclosure, a compound refers to a chemical substance formed by two or more elements bonded with chemical bonds and may comprise a small molecule compound and a polymer compound, but not limited thereto. Any compound disclosed herein is interpreted to not only include a single chemical substance but also include a class of chemical substances having the same kind of components or having the same property.

Unless otherwise specified, according to the present disclosure, a polymer refers to the product formed by monomer(s) via polymerization and usually comprises multiple aggregates of polymers respectively formed by multiple repeated simple structure units by covalent bonds; the monomer refers to the compound forming the polymer. A polymer may comprise a homopolymer, a copolymer, a prepolymer, etc., but not limited thereto. A homopolymer refers to the polymer formed by the polymerization of one monomer. A copolymer refers to the polymer formed by the polymerization of two or more different monomers. Copolymers comprise: random copolymers, such as a structure of -AABABBBAAABBA-; alternating copolymers, such as a structure of -ABABABAB-; graft copolymers, such as a structure of -AA (A-BBBB)AA(A-BBBB)AAA-; and block copolymers, such as a structure of -AAAAA-BBBBBB-AAAAA-. For example, a styrene-butadiene copolymer disclosed herein is interpreted as comprising a styrene-butadiene random copolymer, a styrene-butadiene alternating copolymer, a styrene-butadiene graft copolymer or a styrene-butadiene block copolymer. A prepolymer refers to a polymer having a lower molecular weight between the molecular weight of monomer and the molecular weight of final polymer, and a prepolymer contains a reactive functional group capable of participating further polymerization to obtain the final polymer product which has been fully crosslinked or cured. The term “polymer” includes but is not limited to an oligomer. An oligomer refers to a polymer with 2 to 20, typically 2 to 5, repeating units.

To those of ordinary skill in the art to which this disclosure pertains, a resin composition containing an additive and three compounds (e.g., A, B and C), a total of four components, is different from a resin composition containing the additive and a prepolymer formed by the three compounds (e.g., A, B and C), a total of two components, as they are completely different from each other in the aspects of preparation method, physical or chemical properties of the resin composition and properties of an article or product made therefrom. For example, the former involves mixing A, B, C and the additive to form the resin composition; in contrast, the latter involves first subjecting a mixture comprising A, B and C to a prepolymerization reaction at proper conditions to form a prepolymer and then mixing the prepolymer with the additive to form the resin composition. For example, to those of ordinary skill in the art to which this disclosure pertains, the two resin compositions have completely different compositions; in addition, because the prepolymer formed by A, B and C functions completely different from A, B and C individually or collectively in the resin composition, the two resin compositions should be construed as completely different chemical substances and have completely different chemical statuses. For example, to those of ordinary skill in the art to which this disclosure pertains, because the two resin compositions are completely different chemical substances, articles made therefrom will not have the same properties. For example, to a resin composition containing a crosslinking agent and a prepolymer formed by A, B and C, since A, B and C have been partially reacted or converted during the prepolymerization reaction to form the prepolymer, during the process of heating to semi-cure the resin composition at a high temperature condition, a partial crosslinking reaction occurs between the prepolymer and the crosslinking agent but not between A, B and C individually and the crosslinking agent. As such, articles made from the two resin compositions will be completely different and have completely different properties.

Unless otherwise specified, the term “resin” of the present disclosure is a widely used common name of a synthetic polymer and is construed as comprising monomer and its combination, polymer and its combination or a combination of monomer and its polymer, but not limited thereto.

Unless otherwise specified, according to the present disclosure, a modification comprises a product derived from a resin with its reactive functional group modified, a product derived from a prepolymerization reaction of a resin and other resins, a product derived from a crosslinking reaction of a resin and other resins, a product derived from copolymerizing a resin and other resins, etc.

The unsaturated C═C double bond as used herein preferably comprises, but not limited to, a vinyl group, a vinylbenzyl group, a (meth)acryloyl group, an allyl group or a combination thereof. The term “vinyl group” is construed as comprising a vinyl group and a vinylene group, and the term “(meth)acryloyl group” is construed as comprising an acryloyl group and a methacryloyl group.

Unless otherwise specified, the functional group described herein, such as but not limited to an alkyl group, an alkenyl group and an alkynyl group, is construed to encompass various isomers thereof. For example, a propyl group is construed to encompass n-propyl and iso-propyl. The compounds described herein are construed to encompass various isomers thereof, such as compounds with the same molecular formula but with different substitution positions of a substituent.

Unless otherwise specified, as used herein, part(s) by weight represents weight part(s) in any weight unit in the resin composition, such as but not limited to kilogram, gram, pound and so on. For example, 100 parts by weight of an unsaturated C═C double bond-containing polyphenylene ether resin may represent 100 kilograms of the unsaturated C═C double bond-containing polyphenylene ether resin or 100 pounds of the unsaturated C═C double bond-containing polyphenylene ether resin.

Unless otherwise specified, in the present disclosure, wt % represents weight (or mass) percentage.

It should be understood that all features disclosed herein may be combined in any way to constitute the technical solution of the present disclosure, as long as there is no conflict present in the combination of these features.

Examples and embodiments are described in detail below. It will be understood that these examples and embodiments are exemplary only and are not intended to limit the scope and use of the present disclosure. Unless otherwise specified, processes, reagents and conditions described in the examples are those known in the art.

As described above, the present disclosure mainly provides a resin composition, comprising: (A) 100 parts by weight of an unsaturated C═C double bond-containing polyphenylene ether resin; (B) 5 parts by weight to 100 parts by weight of a compound of Formula (1), a compound of Formula (2), an oligomer of the compound of Formula (1), an oligomer of the compound of Formula (2) or a combination thereof; and (C) 5 parts by weight to 100 parts by weight of a benzocyclobutene-modified polyolefin;

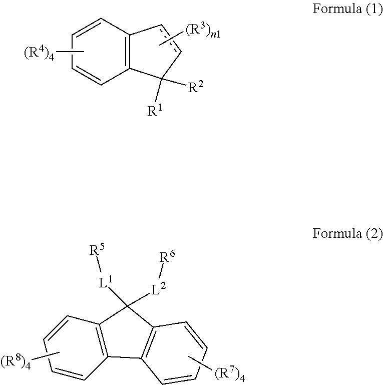

in Formula (1), R¹, R² and R³ are each independently selected from a hydrogen atom, a C₁ to C₅ alkyl group (such as but not limited to methyl, ethyl, n-propyl or isopropyl and various isomers of butyl and pentyl), a vinylphenyl group, a vinylbenzyl group, an allylphenyl group and an allylbenzyl group, and at least one of R¹, R² and R³ is a vinylphenyl group, a vinylbenzyl group, an allylphenyl group or an allylbenzyl group; R⁴ is each independently selected from a hydrogen atom and a C₁ to C₅ alkyl group (such as but not limited to methyl, ethyl, n-propyl or isopropyl and various isomers of butyl and pentyl); [symbol] represents a C—C single bond or a C═C double bond; when [symbol] represents a C—C single bond (Formula (1) has an indane skeleton), n1 is 4 (i.e., Formula (1) has four R³ groups, and each R³ group is independent of each other), and when [symbol] represents a C═C double bond (Formula (1) has an indene skeleton), n1 is 2 (i.e., Formula (1) has two R³ groups, and each R³ group is independent of each other);
in Formula (2), L¹ and L² are each independently selected from a C₁ to C₅ alkylene group (such as but not limited to methylene, ethylene, n-propylene or isopropylene and various isomers of butylene and pentylene) and a C₆ to C₁₂ arylene group (such as phenylene, naphthylene and biphenylene); R⁵ and R⁶ are each independently selected from a hydrogen atom, a C₁ to C₅ alkyl group (such as but not limited to methyl, ethyl, n-propyl or isopropyl and various isomers of butyl and pentyl), a vinylphenyl group, a vinylbenzyl group, an allylphenyl group and an allylbenzyl group, and at least one of R⁵ and R⁶ is a vinylphenyl group, a vinylbenzyl group, an allylphenyl group or an allylbenzyl group; and R⁷ and R⁸ are each independently selected from a hydrogen atom and a C₁ to C₅ alkyl group (such as but not limited to methyl, ethyl, n-propyl or isopropyl and various isomers of butyl and pentyl).

The unsaturated C═C double bond-containing polyphenylene ether resin suitable for the present disclosure is not particularly limited and may be any one or more unsaturated C═C double bond-containing polyphenylene ether resins useful for making a prepreg, a resin film, a laminate or a printed circuit board and may be any one or more commercial products, products prepared by the Applicant or a combination thereof, examples including but not limited to any one of a vinylbenzyl group-containing polyphenylene ether resin, a (meth)acryloyl group-containing polyphenylene ether resin, a vinyl group-containing polyphenylene ether resin, an allyl group-containing polyphenylene ether resin or a combination thereof.

The unsaturated C═C double bond-containing polyphenylene ether resin of the present disclosure has an unsaturated C═C double bond and a phenylene ether skeleton, wherein the unsaturated C═C double bond is a reactive group which may perform self-polymerization under heat and may also perform free radical polymerization with other components with unsaturated bonds in the resin composition and finally result in crosslinking and curing. The cured product thereof has high heat resistance and good dielectric properties. Preferably, the unsaturated C═C double bond-containing polyphenylene ether resin comprises an unsaturated C═C double bond-containing polyphenylene ether resin with 2,6-dimethyl substitution in its phenylene ether skeleton, wherein the methyl groups form steric hindrance to prevent the oxygen atom of the ether group from forming a hydrogen bond or Van der Waals force to absorb moisture, thereby achieving better dielectric properties.

For example, in one embodiment, the unsaturated C═C double bond-containing polyphenylene ether resin comprises, but not limited to, a vinylbenzyl group-containing polyphenylene ether resin with a number average molecular weight of about 1200 (such as OPE-2st 1200, available from Mitsubishi Gas Chemical Co., Inc.), a vinylbenzyl group-containing polyphenylene ether resin with a number average molecular weight of about 2200 (such as OPE-2st 2200, available from Mitsubishi Gas Chemical Co., Inc.), a vinylbenzyl group-containing polyphenylene ether resin with a number average molecular weight of about 2400 to 2800 (such as a vinylbenzyl group-containing bisphenol A polyphenylene ether resin), a (meth)acryloyl group-containing polyphenylene ether resin with a number average molecular weight of about 1900 to 2300 (such as SA9000, available from Sabic), a vinyl group-containing polyphenylene ether resin with a number average molecular weight of about 2200 to 3000, or a combination thereof. The vinyl group-containing polyphenylene ether resin may include various polyphenylene ether resins disclosed in the US Patent Application Publication No. 20160185904A1, all of which are incorporated herein by reference in their entirety. For example, in one embodiment, the vinylbenzyl group-containing polyphenylene ether resin comprises, but not limited to, a vinylbenzyl group-containing biphenyl polyphenylene ether resin, a vinylbenzyl group-containing bisphenol A polyphenylene ether resin or a combination thereof.

Relative to 100 parts by weight of the unsaturated C═C double bond-containing polyphenylene ether resin, the resin composition of the present disclosure further comprises 5 parts by weight to 100 parts by weight of a compound of Formula (1), a compound of Formula (2), an oligomer of the compound of Formula (1), an oligomer of the compound of Formula (2) or a combination thereof. For example, relative to 100 parts by weight of the unsaturated C═C double bond-containing polyphenylene ether resin, the amount of compound of Formula (1), compound of Formula (2), oligomer of the compound of Formula (1), oligomer of the compound of Formula (2) or a combination thereof may be 5, 10, 15, 20, 30, 40, 50, 60, 70, 75, 80, 85, 90, 95 or 100 parts by weight, but not limited thereto. For example, in one embodiment, relative to 100 parts by weight of the unsaturated C═C double bond-containing polyphenylene ether resin, the amount of compound of Formula (1), compound of Formula (2), oligomer of the compound of Formula (1), oligomer of the compound of Formula (2) or a combination thereof is 5 parts by weight to 75 parts by weight.

For example, in one embodiment, the compound of Formula (1) comprises a compound of Formula (1-1), a compound of Formula (1-2), a compound of Formula (1-3), a compound of Formula (1-4) or a combination thereof; and the compound of Formula (2) comprises a compound of Formula (2-1), a compound of Formula (2-2), a compound of Formula (2-3) or a combination thereof. The aforementioned structures may refer to the foregoing description and the claims of this application, and further description thereof is omitted for convenience. Unless otherwise specified, the oligomer of the compound of Formula (1) or the oligomer of the compound of Formula (2) may be obtained by subjecting the compound of Formula (1) or the compound of Formula (2) to a certain degree of polymerization performed by those with ordinary skill in the art. In one embodiment, for example, the average degree of polymerization of the oligomer of the compound of Formula (1) or the oligomer of the compound of Formula (2) may be 2 to 20, but not limited thereto.

For example, in one embodiment, the resin composition of the present disclosure may contain a mixture of the compound of Formula (1) and/or an oligomer thereof and the compound of Formula (2) and/or an oligomer thereof, and the total amount is 5 parts by weight to 100 parts by weight. For example, in one embodiment, the resin composition of the present disclosure may at the same time contain the compound of Formula (1) and/or an oligomer thereof and the compound of Formula (2) and/or an oligomer thereof, and the weight ratio of the compound of Formula (1) and/or an oligomer thereof to the compound of Formula (2) and/or an oligomer thereof is 9:1 to 1:9.

Relative to 100 parts by weight of the unsaturated C═C double bond-containing polyphenylene ether resin, the resin composition of the present disclosure further comprises 5 parts by weight to 100 parts by weight of a benzocyclobutene-modified polyolefin. For example, in one embodiment, relative to 100 parts by weight of the unsaturated C═C double bond-containing polyphenylene ether resin, the resin composition of the present disclosure further comprises 5, 10, 15, 20, 30, 40, 50, 60, 70, 75, 80, 85, 90, 95 or 100 parts by weight of a benzocyclobutene-modified polyolefin, but not limited thereto. For example, in one embodiment, relative to 100 parts by weight of the unsaturated C═C double bond-containing polyphenylene ether resin, the amount of the benzocyclobutene-modified polyolefin is 5 parts by weight to 80 parts by weight.

According to the present disclosure, the benzocyclobutene-modified polyolefin refers to a compound obtained by modifying polyolefin with a halogenated benzocyclobutene. The type of the polyolefin is not particularly limited and may be any one or more polyolefins suitable for preparing a prepreg, a resin film, a laminate or a printed circuit board. For example, in one embodiment, the structure of the polyolefin may contain a heteroatom, such as nitrogen, oxygen, sulfur, phosphorus, silicon and other atoms. For example, in one embodiment, the structure of the polyolefin does not contain a heteroatom; that is, it does not contain atoms other than carbon and hydrogen. For example, in one embodiment, the polyolefin containing a heteroatom comprises any one of maleic anhydride-adducted polybutadiene, maleic anhydride-adducted polyisoprene, maleic anhydride-adducted styrene-butadiene copolymer, maleic anhydride-adducted styrene-isoprene copolymer, vinyl-polybutadiene-urethane polymer, silane-modified styrene-butadiene copolymer, acryloyl-terminated polybutadiene, epoxy-containing polybutadiene, or a combination thereof. These components should be construed as including their modifications or derivatives. For example, in one embodiment, the polyolefin not containing a heteroatom comprises any one of polybutadiene, polyisoprene, styrene-butadiene copolymer, styrene-isoprene copolymer, styrene-butadiene-divinylbenzene polymer, styrene-ethylene-divinylbenzene polymer, styrene-ethylstyrene-divinylbenzene polymer, or a combination thereof. These components should be construed as including their modifications or derivatives.

For example, in one embodiment, the benzocyclobutene-modified polyolefin comprises a benzocyclobutene-modified polybutadiene, a benzocyclobutene-modified polyisoprene, a benzocyclobutene-modified product of styrene-butadiene copolymer, a benzocyclobutene-modified product of styrene-isoprene copolymer, a benzocyclobutene-modified product of styrene-butadiene-divinylbenzene polymer, a benzocyclobutene-modified product of styrene-ethylene-divinylbenzene polymer, a benzocyclobutene-modified product of styrene-ethylstyrene-divinylbenzene polymer, a benzocyclobutene-modified product of maleic anhydride-adducted polybutadiene, a benzocyclobutene-modified product of maleic anhydride-adducted polyisoprene, a benzocyclobutene-modified product of maleic anhydride-adducted styrene-butadiene copolymer, a benzocyclobutene-modified product of maleic anhydride-adducted styrene-isoprene copolymer, a benzocyclobutene-modified product of vinyl-polybutadiene-urethane polymer, a benzocyclobutene-modified product of silane-containing styrene-butadiene copolymer, a benzocyclobutene-modified product of acryloyl-terminated polybutadiene, a benzocyclobutene-modified product of epoxy-containing polybutadiene or a combination thereof.

For example, in one embodiment, the benzocyclobutene-modified polyolefin comprises a benzocyclobutene-modified polyolefin containing a heteroatom, a benzocyclobutene-modified polyolefin not containing a heteroatom or a combination thereof. For example, in one embodiment, the benzocyclobutene-modified polyolefin comprises a benzocyclobutene-modified polyolefin containing a heteroatom and a benzocyclobutene-modified polyolefin not containing a heteroatom at a weight ratio of 2:1 to 1:9. For example, in one embodiment, the resin composition of the present disclosure comprises a benzocyclobutene-modified polyolefin containing a heteroatom and a benzocyclobutene-modified polyolefin not containing a heteroatom at a weight ratio of 2:1, 1:1, 1:2, 1:3, 1:4, 1:5, 1:6, 1:7, 1:8 or 1:9, but not limited thereto.

Unless otherwise specified, according to the resin composition of the present disclosure, the amount of each component contained in the resin composition is represented as the amount relative to 100 parts by weight of the unsaturated C═C double bond-containing polyphenylene ether resin. For example, but not limited thereto, relative to 100 parts by weight of the unsaturated C═C double bond-containing polyphenylene ether resin, the amount of compound of Formula (1), compound of Formula (2), oligomer of the compound of Formula (1), oligomer of the compound of Formula (2) or a combination thereof is 5 parts by weight to 100 parts by weight, such as comprising but not limited to 5 parts by weight, 20 parts by weight, 35 parts by weight, 40 parts by weight, 50 parts by weight, 60 parts by weight, 75 parts by weight or 100 parts by weight, and relative to 100 parts by weight of the unsaturated C═C double bond-containing polyphenylene ether resin, the amount of the benzocyclobutene-modified polyolefin is 5 parts by weight to 100 parts by weight, such as comprising but not limited to 5 parts by weight, 30 parts by weight, 40 parts by weight, 50 parts by weight, 60 parts by weight, 80 parts by weight or 100 parts by weight.

In one embodiment, for example, the resin composition described herein may further optionally comprise a polyolefin different from the benzocyclobutene-modified polyolefin, an organic silicone resin, a benzoxazine resin, an epoxy resin, a polyester resin, a phenol resin, an amine curing agent, a polyamide, a polyimide, a maleimide resin, a cyanate ester resin, a maleimide triazine resin or a combination thereof.

Unless otherwise specified, in the resin composition of the present disclosure, relative to 100 parts by weight of the unsaturated C═C double bond-containing polyphenylene ether resin, the amount of polyolefin different from a benzocyclobutene-modified polyolefin, organic silicone resin, benzoxazine resin, epoxy resin, polyester resin, phenol resin, polyamide, polyimide, maleimide resin, cyanate ester resin and maleimide triazine resin is not particularly limited and may be adjusted according to the need. For example, each component may independently range from 1 part by weight to 100 parts by weight, such as but not limited to 1 part by weight, 5 parts by weight, 10 parts by weight, 15 parts by weight, 20 parts by weight, 25 parts by weight, 50 parts by weight or 100 parts by weight. Relative to 100 parts by weight of the unsaturated C═C double bond-containing polyphenylene ether resin, the amount of the amine curing agent is not particularly limited and may be adjusted according to the need. For example, the amount of the amine curing agent may be 1 part by weight to 30 parts by weight.

For example, the polyolefin different from the benzocyclobutene-modified polyolefin comprises but is not limited to any one of polybutadiene, polyisoprene, styrene-butadiene copolymer, styrene-isoprene copolymer, styrene-butadiene-divinylbenzene polymer, vinyl-polybutadiene-urethane polymer, polymethylstyrene, hydrogenated polybutadiene, hydrogenated polyisoprene, hydrogenated styrene-butadiene-divinylbenzene polymer, hydrogenated styrene-butadiene copolymer, hydrogenated styrene-isoprene copolymer, styrene-ethylene-divinylbenzene polymer, styrene-ethylstyrene-divinylbenzene polymer or a combination thereof.

For example, the organic silicone resin comprises but is not limited to polyalkylsiloxane, polyarylsiloxane, polyalkarylsiloxane, modified polysiloxane or a combination thereof. The modified polysiloxane comprises but is not limited to amino-modified organic silicone resin, epoxy group-modified organic silicone resin, methacryloyl group-modified organic silicone resin, hydroxyl group-modified organic silicone resin, carboxyl group-modified organic silicone resin or a combination thereof. Preferably, the amino-modified organic silicone resin suitable for the present disclosure includes products such as KF-8010, X-22-161A, X-22-161B, KF-8012, KF-8008, X-22-9409 and X-22-1660B-3 available from Shin-Etsu Chemical Co., Ltd., products such as BY-16-853U, BY-16-853 and BY-16-853B available from Toray-Dow corning Co., Ltd., products such as XF42-C5742, XF42-C6252 and XF42-C5379 available from Momentive Performance Materials JAPAN LLC, or a combination thereof. The epoxy group-modified organic silicone resin suitable for the present disclosure includes, for example, X-22-163 series available from Shin-Etsu Chemical Co., Ltd. The methacryloyl group-modified organic silicone resin suitable for the present disclosure includes, for example, X-22-164 series available from Shin-Etsu Chemical Co., Ltd.

For example, the benzoxazine resin comprises but is not limited to bisphenol A benzoxazine resin, bisphenol F benzoxazine resin, phenolphthalein benzoxazine resin, dicyclopentadiene benzoxazine resin, phosphorus-containing benzoxazine resin, diamine benzoxazine resin and phenyl group-modified, vinyl group-modified or allyl group-modified benzoxazine resin. Commercially available products include LZ-8270 (phenolphthalein benzoxazine resin), LZ-8298 (phenolphthalein benzoxazine resin), LZ-8280 (bisphenol F benzoxazine resin) and LZ-8290 (bisphenol A benzoxazine resin) available from Huntsman, and KZH-5031 (vinyl group-modified benzoxazine resin) and KZH-5032 (phenyl group-modified benzoxazine resin) available from Kolon Industries Inc. The diamine benzoxazine resin may be diaminodiphenylmethane benzoxazine resin, diaminodiphenyl ether benzoxazine resin, diaminodiphenyl sulfone benzoxazine resin, diaminodiphenyl sulfide benzoxazine resin or a combination thereof, but not limited thereto.

For example, the epoxy resin may be any epoxy resins known in the field to which this disclosure pertains. In terms of improving the heat resistance of the resin composition, the epoxy resin may include, but not limited to, any one of bisphenol A epoxy resin, bisphenol F epoxy resin, bisphenol S epoxy resin, bisphenol AD epoxy resin, novolac epoxy resin, trifunctional epoxy resin, tetrafunctional epoxy resin, multifunctional novolac epoxy resin, dicyclopentadiene (DCPD) epoxy resin, phosphorus-containing epoxy resin, p-xylene epoxy resin, naphthalene epoxy resin (e.g., naphthol epoxy resin), benzofuran epoxy resin, isocyanate-modified epoxy resin, or a combination thereof. According to the present disclosure, for example, the novolac epoxy resin may be phenol novolac epoxy resin, bisphenol A novolac epoxy resin, bisphenol F novolac epoxy resin, biphenyl novolac epoxy resin, phenol benzaldehyde epoxy resin, phenol aralkyl novolac epoxy resin or o-cresol novolac epoxy resin. According to the present disclosure, for example, the phosphorus-containing epoxy resin may be DOPO (9,10-dihydro-9-oxa-10-phosphaphenanthrene-10-oxide) epoxy resin, DOPO-HQ epoxy resin or a combination thereof. The DOPO epoxy resin may be any one or more selected from DOPO-containing phenol novolac epoxy resin, DOPO-containing o-cresol novolac epoxy resin and DOPO-containing bisphenol-A novolac epoxy resin; the DOPO-HQ epoxy resin may be any one or more selected from DOPO-HQ-containing phenol novolac epoxy resin, DOPO-HQ-containing o-cresol novolac epoxy resin and DOPO-HQ-containing bisphenol-A novolac epoxy resin, but not limited thereto.

For example, the polyester resin may be any polyester resins known in the field to which this disclosure pertains. Examples include but are not limited to a dicyclopentadiene-containing polyester resin, a biphenyl-containing polyester resin and a naphthalene-containing polyester resin. Examples include but are not limited to HPC-8000, HPC-8800 or HPC-8150 available from D.I.C. Corporation.

For example, the phenol resin may be any phenol resins known in the field to which this disclosure pertains. Examples include but are not limited to novolac resin or phenoxy resin, wherein the novolac resin includes but not limited to phenol novolac resin, o-cresol novolac resin, bisphenol A novolac resin, naphthol novolac resin, biphenyl novolac resin, and dicyclopentadiene phenol resin.

For example, the amine curing agent may be any amine curing agents known in the field to which this disclosure pertains. Examples include but are not limited to diamino diphenyl sulfone, diamino diphenyl methane, diamino diphenyl ether, diamino diphenyl sulfide and dicyandiamide.

For example, the polyamide may be any polyamides known in the field to which this disclosure pertains. Examples include but are not limited to various commercially available polyamide resin products.

For example, the polyimide may be any polyimides known in the field to which this disclosure pertains. Examples include but are not limited to various commercially available polyimide resin products.

For example, the maleimide resin may be any maleimide resins known in the field to which this disclosure pertains. Examples include but are not limited to: 4,4′-diphenylmethane bismaleimide, polyphenylmethane maleimide (a.k.a. oligomer of phenylmethane maleimide), bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl) hexane, N-2,3-xylylmaleimide, N-2,6-xylylmaleimide, N-phenylmaleimide, vinyl benzyl maleimide (VBM), maleimide containing biphenyl structure, maleimide containing isopropyl and m-arylene structures, maleimide containing indane structure, maleimide resin containing a C₁₀ to C₅₀ aliphatic structure, prepolymer of diallyl compound and maleimide resin, prepolymer of diamine and maleimide resin, prepolymer of multi-functional amine and maleimide resin, prepolymer of acid phenol compound and maleimide resin, or a combination thereof. These components should be construed as including their modifications.

For example, the maleimide resin includes but is not limited to products such as BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000, and BMI-7000H available from Daiwakasei Industry, products such as BMI-70 and BMI-80 available from K.I Chemical Industry Co., Ltd., products such as MIR-3000 and MIR-5000 available from Nippon Kayaku and maleimide resins containing an indane structure available from DIC.

For example, the maleimide resin containing a C₁₀ to C₅₀ aliphatic structure, also known as imide-extended maleimide resin, may include various imide-extended maleimide resins disclosed in the TW Patent Application Publication No. 200508284A, all of which are incorporated herein by reference in their entirety. Examples of the maleimide resin containing a C₁₀ to C₅₀ aliphatic structure suitable for the present disclosure may include, but not limited to, products such as BMI-689, BMI-1400, BMI-1500, BMI-1700, BMI-2500, BMI-3000, BMI-5000 and BMI-6000 available from Designer Molecules Inc.

For example, the cyanate ester may be any cyanate ester resins known in the field to which this disclosure pertains, such as a compound having an Ar—O—C≡N structure, wherein Ar may be a substituted or unsubstituted aromatic group. In terms of improving the heat resistance of the resin composition, examples include but are not limited to novolac cyanate ester resin, bisphenol A cyanate ester resin, bisphenol F cyanate ester resin, dicyclopentadiene-containing cyanate ester resin, naphthalene-containing cyanate ester resin, phenolphthalein cyanate ester resin, adamantane cyanate ester resin, fluorene cyanate ester resin or a combination thereof. The novolac cyanate ester resin may be bisphenol A novolac cyanate ester resin, bisphenol F novolac cyanate ester resin or a combination thereof. For example, the cyanate ester resin may be available under the product name Primaset PT-15, PT-30S, PT-60S, BA-200, BA-230S, BA-3000S, BTP-2500, BTP-6020S, DT-4000, DT-7000, ULL950S, HTL-300, CE-320, LVT-50, or LeCy sold by Arxada AG

For example, the maleimide triazine resin may be any maleimide triazine resins known in the field to which this disclosure pertains. Examples include but are not limited to: the maleimide triazine resin obtained by polymerizing bisphenol A cyanate ester resin and maleimide resin, the maleimide triazine resin obtained by polymerizing bisphenol F cyanate ester resin and maleimide resin, the maleimide triazine resin obtained by polymerizing phenol novolac cyanate ester resin and maleimide resin and the maleimide triazine resin obtained by polymerizing dicyclopentadiene-containing cyanate ester resin and maleimide resin. In one embodiment, the maleimide triazine resin can be obtained by polymerizing the maleimide resin and the cyanate ester resin in any molar ratio. For example, the molar ratio of maleimide resin to cyanate ester resin may be from 1:1 to 1:10, such as but not limited to 1:1, 1:2, 1:4, 1:6, 1:8 or 1:10.

In one embodiment, for example, the resin composition further comprises curing accelerator, polymerization inhibitor, flame retardant, inorganic filler, surface treating agent, coloring agent, toughening agent, solvent or a combination thereof.

For example, the curing accelerator may comprise a catalyst, such as a Lewis base or a Lewis acid. The Lewis base may comprise any one or more of imidazole, boron trifluoride-amine complex, ethyltriphenyl phosphonium chloride, 2-methylimidazole (2 MI), 2-phenyl-1H-imidazole (2PZ), 2-ethyl-4-methylimidazole (2E4MZ), triphenylphosphine (TPP) and 4-dimethylaminopyridine (DMAP). The Lewis acid may comprise metal salt compounds, such as those of manganese, iron, cobalt, nickel, copper and zinc, such as zinc octanoate or cobalt octanoate. The curing accelerator also includes a curing initiator, such as a peroxide capable of producing free radicals, examples of curing initiator including but not limited to dicumyl peroxide (DCP), tert-butyl peroxybenzoate, dibenzoyl peroxide (BPO), 2,5-dimethyl-2,5-di(tert-butylperoxy)-3-hexyne (25B), bis(tert-butylperoxy isopropyl)benzene or a combination thereof. For example, in one embodiment, relative to 100 parts by weight of the unsaturated C═C double bond-containing polyphenylene ether resin, the resin composition of the present disclosure may further comprise 0.01 part by weight to 5.0 parts by weight of a curing accelerator, preferably 0.1 part by weight to 4.0 parts by weight of a curing accelerator, more preferably 0.5 part by weight to 2.0 parts by weight of a curing accelerator, but not limited thereto.

For example, the polymerization inhibitor may comprise, but not limited to, 1,1-diphenyl-2-picrylhydrazyl radical, methyl acrylonitrile, nitroxide-mediated radical, triphenylmethyl radical, metal ion radical, sulfur radical (such as including but not limited to dithioester), hydroquinone, 4-methoxyphenol, p-benzoquinone, phenothiazine, β-phenylnaphthylamine, 4-t-butylcatechol, methylene blue, 4,4′-butylidenebis(6-t-butyl-3-methylphenol) and 2,2′-methylenebis(4-ethyl-6-t-butylphenol) or a combination thereof. For example, the nitroxide-mediated radical may comprise, but not limited to, nitroxide radicals derived from cyclic hydroxylamines, such as 2,2,6,6-substituted piperidine 1-oxyl free radical, 2,2,5,5-substituted pyrrolidine 1-oxyl free radical or the like. Preferred substitutes include alkyl groups with 4 or fewer carbon atoms, such as methyl group or ethyl group. Examples of the compound containing a nitroxide radical include but are not limited to 2,2,6,6-tetramethyl piperidine 1-oxyl free radical, 2,2,6,6-tetraethylpiperidine 1-oxyl free radical, 2,2,6,6-tetramethyl-4-oxo-piperidine 1-oxyl free radical, 2,2,5,5-tetramethylpyrrolidine 1-oxyl free radical, 1,1,3,3-tetramethyl-2-isoindoline oxygen radical, N,N-di-tert-butylamine oxygen free radical and so on. Nitroxide radicals may also be replaced by using stable radicals such as galvinoxyl radicals. The polymerization inhibitor suitable for the resin composition of the present disclosure may include products derived from the polymerization inhibitor with its hydrogen atom or group substituted by other atom or group. Examples include products derived from a polymerization inhibitor with its hydrogen atom substituted by an amino group, a hydroxyl group, a carbonyl group or the like. For example, in one embodiment, relative to 100 parts by weight of the unsaturated C═C double bond-containing polyphenylene ether resin, the resin composition of the present disclosure may further comprise 0.001 part by weight to 20 parts by weight of a polymerization inhibitor, preferably 0.01 part by weight to 10 parts by weight of a polymerization inhibitor, but not limited thereto.

For example, the flame retardant comprises but is not limited to a phosphorus-containing flame retardant or a bromine-containing flame retardant. The bromine-containing flame retardant preferably comprises decabromodiphenyl ethane. The phosphorus-containing flame retardant may preferably include: hydroquinone bis-(diphenyl phosphate), bisphenol A bis-(diphenylphosphate), tri(2-carboxyethyl) phosphine (TCEP), phosphoric acid tris(chloroisopropyl) ester, trimethyl phosphate (TMP), dimethyl methyl phosphonate (DMMP), resorcinol bis(dixylenyl phosphate) (RDXP, such as commercially available PX-200, PX-201, and PX-202), ammonium polyphosphate, melamine polyphosphate, phosphazene (such as commercially available SPB-100, SPH-100, and SPV-100), 9,10-dihydro-9-oxa-10-phosphaphenanthrene-10-oxide (DOPO) compound and its derivatives or resins (e.g., di-DOPO compound), diphenylphosphine oxide (DPPO) compound and its derivatives or resins (e.g., di-DPPO compound), melamine cyanurate, tri-hydroxy ethyl isocyanurate, aluminium phosphinate (e.g., commercially available OP-930 and OP-935), or a combination thereof.

For example, the flame retardant may be a flame retardant commercially available from Katayama Chemical Industries Co., Ltd., such as but not limited to V1, V2, V3, V4, V5, V7, S-2, S-4, E-4c, E-7c, E-8g, E-9g, E-10g, E-100, B-3, W-10, W-2h, W-20, W-30, W-40, OX-1, OX-2, OX-4, OX-6, OX-6+, OX-7, OX-7+, OX-13, BPE-1, BPE-3, HyP-2, API-9, CMPO, ME-20, C-1R, C-1S, C-3R, C-3S or C-11R. The flame retardant of the present disclosure may include one or more of the above flame retardants.

For example, in one embodiment, relative to 100 parts by weight of the unsaturated C═C double bond-containing polyphenylene ether resin, the resin composition of the present disclosure may further comprise 1 part by weight to 100 parts by weight of a flame retardant, preferably 5 parts by weight to 50 parts by weight of a flame retardant.

For example, the inorganic filler may include but is not limited to: silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride, zirconium tungstate, petalite, calcined kaolin or a combination thereof. Moreover, the inorganic filler can be spherical (including solid sphere or hollow sphere), fibrous, plate-like, particulate, flake-like or whisker-like and can be optionally pretreated by a silane coupling agent. In addition, inorganic fillers may be prepared by using various methods, such as melting, combustion or chemical synthesis. In addition, the particle size of the inorganic filler is not particularly limited, and the median particle size D50 may be 1 to 45 μm, preferably 1 to 15 μm and more preferably 1 to 10 μm. For example, in one embodiment, relative to 100 parts by weight of the unsaturated C═C double bond-containing polyphenylene ether resin, the resin composition of the present disclosure may further comprise 10 parts by weight to 350 parts by weight of an inorganic filler, preferably 50 parts by weight to 350 parts by weight of an inorganic filler and more preferably 100 parts by weight to 350 parts by weight of an inorganic filler, but not limited thereto.

For example, the surface treating agent comprises but is not limited to silane (such as siloxane), which may be further categorized according to the functional groups into amino silane, epoxide silane, vinyl silane, hydroxyl silane, isocyanate silane, methacryloxy silane and acryloxy silane. The purpose of the surface treating agent used herein is to ensure uniform distribution of the inorganic filler in the resin composition. For example, in one embodiment, relative to 100 parts by weight of the unsaturated C═C double bond-containing polyphenylene ether resin, the resin composition of the present disclosure may further comprise 0.001 part by weight to 20 parts by weight of a surface treating agent, preferably 0.01 part by weight to 10 parts by weight of a surface treating agent, but not limited thereto.

For example, the coloring agent may comprise but is not limited to dye or pigment. For example, in one embodiment, relative to 100 parts by weight of the unsaturated C═C double bond-containing polyphenylene ether resin, the resin composition of the present disclosure may further comprise 0.001 part by weight to 10 parts by weight of coloring agent, preferably 0.01 part by weight to 5 parts by weight of coloring agent, but not limited thereto.

For example, the toughening agent may comprise, but not limited to, carboxyl-terminated butadiene acrylonitrile rubber (CTBN rubber), core-shell rubber, ethylene propylene rubber or a combination thereof. For example, in one embodiment, relative to 100 parts by weight of the unsaturated C═C double bond-containing polyphenylene ether resin, the resin composition of the present disclosure may further comprise 1 part by weight to 20 parts by weight of toughening agent, preferably 3 parts by weight to 10 parts by weight of toughening agent, but not limited thereto.

For example, the solvent comprises but is not limited to: methanol, ethanol, ethylene glycol monomethyl ether, acetone, butanone (methyl ethyl ketone), methyl isobutyl ketone, cyclohexanone, N-methyl-pyrrolidone, toluene, xylene, methoxyethyl acetate, ethoxyethyl acetate, propoxyethyl acetate, ethyl acetate, dimethylformamide, dimethylacetamide, propylene glycol methyl ether acetate, or a mixture thereof. The amount of a solvent is added with the aim of fully dissolving the resin and achieving a specific total solid content of the resin composition. For example, in one embodiment, the amount of the solvent is added in order to adjust the total solid content of the resin composition to 50% to 85% (weight percentage), but not limited thereto.

In addition to the aforesaid resin composition, the present disclosure also provides an article made from the resin composition, such as those suitable for use as components in various electronic products, including but not limited to a prepreg, a resin film, a laminate or a printed circuit board.

For example, the resin composition of the present disclosure can be used to make a prepreg, which comprises a reinforcement material and a layered structure disposed thereon. The layered structure is formed by heating the resin composition at a high temperature to the semi-cured state (B-stage). Suitable baking temperature for making a prepreg may be for example 100° C. to 180° C., preferably 120° C. to 160° C. For example, the reinforcement material may be any one of a fiber material, woven fabric, and non-woven fabric, and the woven fabric preferably comprises fiberglass fabrics. The types of fiberglass fabrics are not particularly limited and may be any fiberglass fabric used for various printed circuit boards, such as E-glass fabric, D-glass fabric, S-glass fabric, T-glass fabric, L-glass fabric, Q-glass fabric or QL-glass fabric (glass fabric with hybrid structure made of Q-glass and L-glass); the fiber may comprise yarns and rovings, in spread form or standard form, and the shape of terminal face may be round or flat. Non-woven fabric preferably comprises liquid crystal polymer non-woven fabric, such as polyester non-woven fabric, polyurethane non-woven fabric and so on, but not limited thereto. Woven fabric may also comprise liquid crystal polymer woven fabric, such as polyester woven fabric, polyurethane woven fabric and so on, but not limited thereto. The reinforcement material may increase the mechanical strength of the prepreg. In one preferred embodiment, the reinforcement material can also be optionally pre-treated by a silane coupling agent. The prepreg may be further heated and cured to the cured state (C-stage) to form an insulation layer.

For example, the resin composition of the disclosure can be used to make a resin film, which is prepared by heating and baking to semi-cure the resin composition. The resin composition may be selectively coated on a supporting material, which includes but is not limited to a liquid crystal polymer film, a polytetrafluoroethylene film, a polyethylene terephthalate film (PET film), a polyimide film (PI film), a metal foil or a resin-coated copper (RCC), followed by heating and baking to semi-cure the resin composition to form the resin film.

For example, the resin composition of the present disclosure may be made into a laminate, which comprises at least two metal foils and at least one insulation layer disposed between the metal foils, wherein the insulation layer is made by curing the resin composition at high temperature and high pressure to the C-stage, a suitable curing temperature being for example between 190° C. and 250° C. and preferably between 200° C. and 220° C. and a suitable curing time being 90 to 180 minutes and preferably 120 to 150 minutes, a suitable lamination pressure being for example between 300 psi and 550 psi and preferably between 400 psi and 550 psi. The insulation layer may be obtained by curing the aforesaid prepreg or resin film. The metal foil may contain copper, aluminum, nickel, platinum, silver, gold or alloy thereof, such as a copper foil. In a preferred embodiment, the laminate is a copper-clad laminate.

In one embodiment, the laminate may be further processed by circuit formation processes to obtain a printed circuit board. In one embodiment of making the printed circuit board according to the present disclosure, a double-sided copper-clad laminate (such as product EM-827, available from Elite Electronic Material (Kunshan) Co., Ltd.) with a thickness of 28 mil and having 1-ounce (oz) HTE (high temperature elongation) copper foils may be used and subject to drilling and then electroplating, so as to form electrical conduction between the top layer copper foil and the bottom layer copper foil. Then the top layer copper foil and the bottom layer copper foil are etched to form inner layer circuit board. Then brown oxidation and roughening are performed on the inner layer circuit board to form uneven structures on the surface to increase roughness. Next, a vacuum lamination apparatus is used to laminate the assembly of a copper foil, the prepreg, the inner layer circuit board, the prepreg and a copper foil stacked in said order by heating at 190° C. to 220° C. for 90 minutes to 180 minutes to cure the insulation material of the prepregs. Next, black oxidation, drilling, copper plating and other known circuit board processes are performed on the outmost copper foils so as to obtain the printed circuit board.

For example, in one embodiment, an article made from the resin composition from each embodiment contains a reinforcement material or a supporting material and a semi-cured or cured product obtained by heating and chemically crosslinking the resin composition.

For example, in one embodiment, the resin composition disclosed herein or various articles made therefrom may preferably have any one, more or all of the following properties:
a difference in post-plating copper foil peeling strength between peripheral area and central area as measured and calculated by reference to IPC-TM-650 2.4.8 of less than or equal to 0.34 lb/in, such as between 0.04 lb/in and 0.34 lb/in or between 0.04 lb/in and 0.20 lb/in; a solder floating delamination rate as measured by reference to IPC-TM-650 2.4.13.1 of less than or equal to 5%, such as between 0% and 5% or such as a solder floating delamination rate of 0%;
a Z-axis coefficient of thermal expansion as measured by reference to IPC-TM-650 2.4.24.5 of less than or equal to 43 ppm/° C., such as between 26 ppm/° C. and 43 ppm/° C.;
a storage modulus variation rate as measured and calculated by reference to IPC-TM-650 2.4.24.4 of less than or equal to 40%, such as between 25% and 40%; and
absence of microvoids on the surface of a laminate section as measured by using focused ion beam (FIB) processing and imaging technology (i.e., microvoid grade of Grade A).

Raw materials below were used to prepare the resin compositions of various Examples and Comparative Examples of the present disclosure according to the amount listed in Table 1 to Table 6 and further fabricated to prepare test samples.

Materials and reagents used in Examples and Comparative Examples disclosed herein are listed below:
SA9000: (meth)acryloyl group-containing polyphenylene ether resin, available from Sabic. OPE-2st 1200: vinylbenzyl group-containing polyphenylene ether resin, available from Mitsubishi Gas Chemical Co., Inc.
OPE-2st 2200: vinylbenzyl group-containing polyphenylene ether resin, available from Mitsubishi Gas Chemical Co., Inc.
Compound of Formula (1-1): having a structure as shown above, wherein the vinyl group is at the para-position, available from Shanghai Aladdin Bio-Chem Technology Co., Ltd.
Compound of Formula (1-2): having a structure as shown above, wherein the vinyl group is at the para-position, available from Shanghai Aladdin Bio-Chem Technology Co., Ltd.
Compound of Formula (2-1): having a structure as shown above, wherein the vinyl group is at the para-position, available from Shanghai Aladdin Bio-Chem Technology Co., Ltd.
Compound of Formula (2-2): having a structure as shown above, wherein the vinyl group is at the para-position, available from Shanghai Aladdin Bio-Chem Technology Co., Ltd.
Compound of Formula (3-1): oligomer of the compound of Formula (2-2), obtained by polymerization of the compound of Formula (2-2), as shown below, wherein m is 7 to 10.

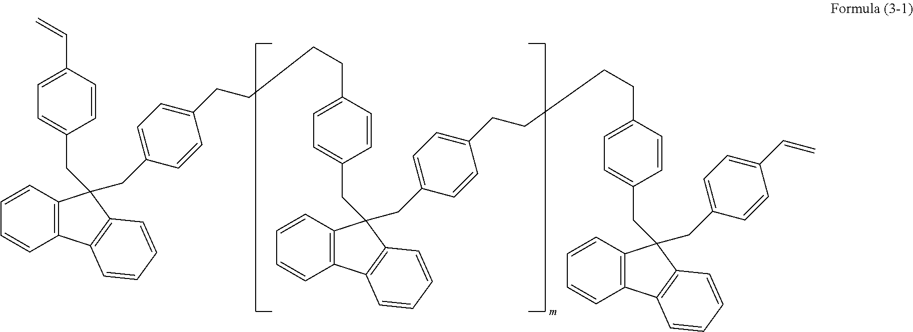

P1 to P10: benzocyclobutene-modified polyolefin, prepared according to Preparation Example 1 to Preparation Example 10.
B-1000: polybutadiene, available from Nippon Soda Co., Ltd.
B-3000: polybutadiene, available from Nippon Soda Co., Ltd.
Ricon 100: styrene-butadiene copolymer, available from Cray Valley.
SBS-A: styrene-butadiene block copolymer, available from Nippon Soda.
Ricon 131MA5: maleic anhydride-adducted polybutadiene, available from Cray Valley.
Ricon 156MA17: maleic anhydride-adducted polybutadiene, available from Cray Valley.
Ricon 184MA6: maleic anhydride-adducted styrene-butadiene copolymer, available from Cray Valley.
EA-3000: acryloyl-terminated polybutadiene, available from Nippon Soda Co., Ltd.
X-12-1281A-ES: silane-containing styrene-butadiene copolymer, available from Shin-Etsu Chemical Co., Ltd.
JP-100: epoxy group-containing polybutadiene, available from Nippon Soda Co., Ltd.
B1: as shown below, commercially available.

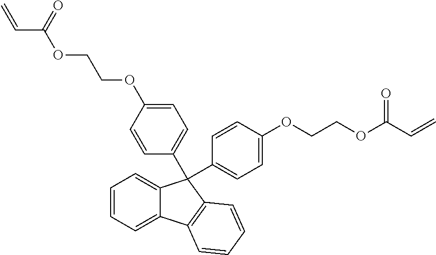 [SMILES: C=CC(=O)OCCOc1ccc(C2(c3ccc(OCCOC(=O)C=C)cc3)c3ccccc3-c3ccccc32)cc1]

DVB: divinylbenzene, available from Shanghai Macklin Biochemical Co., Ltd.
TAIC: triallyl isocyanurate, available from Sartomer.
C1: as shown below, wherein n is 1 to 10, commercially available.

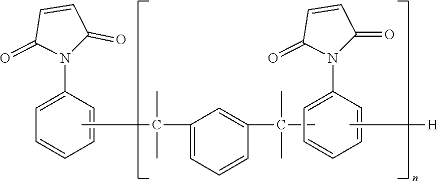

Indane MI: as shown below, wherein n is 0.5 to 20, commercially available.

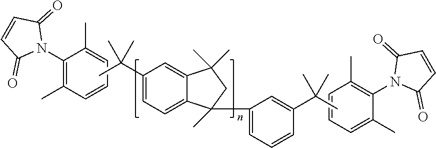

25B: 2,5-dimethyl-2,5-di(t-butylperoxy)-3-hexyne, available from NOF Corporation.
Synthesized spherical silica: median particle size D50 of about 2.5±2 μm, prepared by microemulsion, chemically synthesized spherical silica with surface treated by silane coupling agent, commercially available.
Solvent: weight ratio of toluene and methyl ethyl ketone is 2:1, and toluene and methyl ethyl ketone are commercially available. The amount of solvent is shown as “proper amount”, abbreviated as “PA”, to represent an amount of solvent used to achieve a 60% to 68% total solid content (S/C=60% to 68%) of the resin composition.

### Preparation Example 1

Raw materials containing B-1000 (200 g) and 4-bromobenzocyclobutene (183 g) were added to a reactor, followed by adding a catalyst palladium acetate (4.5 g), tri(o-methylphenyl)phosphine (30.4 g), triethylamine (202 g) and a solvent mixture consisting of anhydrous acetonitrile/N,N-dimethylformamide (DMF) (2000 mL). The solution was evacuated and introduced with nitrogen repeatedly for 3 times and then reacted by heating and refluxing under nitrogen protection for 36 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellowish viscous liquid P1, which was a benzocyclobutene-modified polyolefin, i.e., benzocyclobutene-modified B-1000.

Polyethylene (PE, bromine content: 5000 ppm) was used as a standard sample, and X-ray fluorescence was used to analyze the Product P1 obtained in Preparation Example 1. The results were shown in the sole FIGURE, with photon energy intensity (KeV) as the abscissa and count rate per second (cps) as the ordinate, and the calculated bromine content in PI is 8703 ppm.

### Preparation Example 2

Raw materials containing B-3000 (200 g) and 4-bromobenzocyclobutene (183 g) were added to a reactor, followed by adding a catalyst palladium acetate (4.5 g), tri(o-methylphenyl)phosphine (30.4 g), triethylamine (202 g) and a solvent mixture consisting of anhydrous acetonitrile/DMF (3000 mL). The solution was evacuated and introduced with nitrogen repeatedly for 3 times and then reacted by heating and refluxing under nitrogen protection for 48 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellowish viscous liquid P2, which was a benzocyclobutene-modified polyolefin, i.e., benzocyclobutene-modified B-3000.

### Preparation Example 3

Raw materials containing Ricon 100 (450 g) and 4-bromobenzocyclobutene (183 g) were added to a reactor, followed by adding a catalyst palladium acetate (6.75 g), tri(o-methylphenyl)phosphine (36.48 g), triethylamine (202 g) and a solvent mixture consisting of anhydrous acetonitrile/DMF (3500 mL). The solution was evacuated and introduced with nitrogen repeatedly for 3 times and then reacted by heating and refluxing under nitrogen protection for 72 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellowish viscous liquid P3, which was a benzocyclobutene-modified polyolefin, i.e., benzocyclobutene-modified Ricon 100.

### Preparation Example 4

Raw materials containing SBS-A (260 g) and 4-bromobenzocyclobutene (128.1 g) were added to a reactor, followed by adding a catalyst palladium acetate (4.5 g), tri(o-methylphenyl)phosphine (30.4 g), triethylamine (101 g) and a solvent mixture consisting of anhydrous acetonitrile/cyclohexane/DMF (3000 mL). The solution was evacuated and introduced with nitrogen repeatedly for 3 times and then reacted by heating and refluxing under nitrogen protection for 72 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellowish solid P4, which was a benzocyclobutene-modified polyolefin, i.e., benzocyclobutene-modified SBS-A.

### Preparation Example 5

Raw materials containing Ricon 131MA5 (470 g) and 4-bromo benzocyclobutene (183 g) were added to a reactor, followed by adding a catalyst palladium acetate (6.75 g), tri(o-methylphenyl)phosphine (36.48 g), triethylamine (202 g) and a solvent mixture consisting of anhydrous acetonitrile/DMF (3500 mL). The solution was evacuated and introduced with nitrogen repeatedly for 3 times and then reacted by heating and refluxing under nitrogen protection for 50 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellow viscous liquid P5, which was a benzocyclobutene-modified polyolefin, i.e., benzocyclobutene-modified Ricon 131MA5.

### Preparation Example 6

Raw materials containing Ricon 156MA17 (250 g) and 4-bromo benzocyclobutene (183 g) were added to a reactor, followed by adding a catalyst palladium acetate (6.75 g), tri(o-methylphenyl)phosphine (36.48 g), triethylamine (202 g) and a solvent mixture consisting of anhydrous acetonitrile/DMF (3500 mL). The solution was evacuated and introduced with nitrogen repeatedly for 3 times and then reacted by heating and refluxing under nitrogen protection for 60 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellow viscous liquid P6, which was a benzocyclobutene-modified polyolefin, i.e., benzocyclobutene-modified Ricon 156MA17.

### Preparation Example 7

Raw materials containing Ricon 184MA6 (455 g) and 4-bromo benzocyclobutene (128.1 g) were added to a reactor, followed by adding a catalyst palladium acetate (4.5 g), tri(o-methylphenyl)phosphine (30.4 g), triethylamine (101 g) and a solvent mixture consisting of anhydrous acetonitrile/DMF (3000 mL). The solution was evacuated and introduced with nitrogen repeatedly for 3 times and then reacted by heating and refluxing under nitrogen protection for 72 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellow viscous liquid P7, which was a benzocyclobutene-modified polyolefin, i.e., benzocyclobutene-modified Ricon 184MA6.

### Preparation Example 8

Raw materials containing EA-3000 (200 g) and 4-bromobenzocyclobutene (183 g) were added to a reactor, followed by adding a catalyst palladium acetate (4.5 g), tri(o-methylphenyl)phosphine (30.4 g), triethylamine (202 g) and a solvent mixture consisting of anhydrous acetonitrile/DMF (3000 mL). The solution was evacuated and introduced with nitrogen repeatedly for 3 times and then reacted by heating and refluxing under nitrogen protection for 48 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellow viscous liquid P8, which was a benzocyclobutene-modified polyolefin, i.e., benzocyclobutene-modified EA-3000.

### Preparation Example 9

Raw materials containing X-12-1281A-ES (455 g) and 4-bromo benzocyclobutene (128.1 g) were added to a reactor, followed by adding a catalyst palladium acetate (4.5 g), tri(o-methylphenyl)phosphine (30.4 g), triethylamine (101 g) and a solvent mixture consisting of anhydrous acetonitrile/cyclohexane/DMF (3000 mL). The solution was evacuated and introduced with nitrogen repeatedly for 3 times and then reacted by heating and refluxing under nitrogen protection for 72 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellowish solid P9, which was a benzocyclobutene-modified polyolefin, i.e., benzocyclobutene-modified X-12-1281A-ES.

### Preparation Example 10

Raw materials containing JP-100 (260 g) and 4-bromobenzocyclobutene (183 g) were added to a reactor, followed by adding a catalyst palladium acetate (4.5 g), tri(o-methylphenyl)phosphine (30.4 g), triethylamine (202 g) and a solvent mixture consisting of anhydrous acetonitrile/DMF (2000 mL). The solution was evacuated and introduced with nitrogen repeatedly for 3 times and then reacted by heating and refluxing under nitrogen protection for 40 hours. The bromine content was tested by using X-ray fluorescence (XRF) analysis; when the bromine content was below 10000 ppm, heating was stopped. The solution was cooled to room temperature, added with petroleum ether and stirred, and filtered to remove the salt produced during the reaction and the palladium catalyst; then the filtrate was subject to column chromatography and rotary evaporation to obtain yellowish viscous liquid P10, which was a benzocyclobutene-modified polyolefin, i.e., benzocyclobutene-modified JP-100.

Compositions and test results of resin compositions of Examples and Comparative Examples used herein are listed below in Table 1 to Table 6 (in part by weight):

TABLE 1
Resin compositions of Examples (in part by weight) and test results

| Component | | E1 | E2 | E3 | E4 | E5 | E6 |
|---|---|---|---|---|---|---|---|
| unsaturated C═C double | SA9000 | 100 | 100 | 100 | 100 | 100 | 100 |
| bond-containing | OPE-2st 1200 | | | | | | |
| polyphenylene ether resin | OPE-2st 2200 | | | | | | |
| compound of Formula (1) | Formula (1-1) | | | | | 50 | |
| | Formula (1-2) | | | | | | 50 |
| compound of Formula (2) | Formula (2-1) | | | | | | |
| | Formula (2-2) | 5 | 100 | 50 | 50 | | |
| oligomer of compound of | Formula (3-1) | | | | | | |
| Formula (2) | | | | | | | |
| benzocyclobutene-modified | P1 | 50 | 50 | 5 | 100 | 50 | 50 |
| polyolefin | P2 | | | | | | |
| | P3 | | | | | | |
| | P4 | | | | | | |
| | P5 | | | | | | |
| | P6 | | | | | | |
| | P7 | | | | | | |
| | P8 | | | | | | |
| | P9 | | | | | | |
| | P10 | | | | | | |
| Ricon 100 | | | | | | | |
| B-1000 | | | | | | | |
| B1 | | | | | | | |
| DVB | | | | | | | |
| TAIC | | | | | | | |
| C1 | | | | | | | |
| indane MI | | | | | | | |
| curing accelerator | 25B | 1 | 1 | 1 | 1 | 1 | 1 |
| inorganic filler | synthesized | 220 | 220 | 220 | 220 | 220 | 220 |
| | spherical silica | | | | | | |
| solvent | toluene:MEK = 2:1 | PA | PA | PA | PA | PA | PA |

| Item | Unit | E1 | E2 | E3 | E4 | E5 | E6 |
|---|---|---|---|---|---|---|---|
| post-plating P/S uniformity | lb/in | 0.31 | 0.32 | 0.26 | 0.34 | 0.33 | 0.34 |
| solder floating delamination | % | 0 | 3 | 0 | 5 | 0 | 0 |
| rate | | | | | | | |
| Z-CTE | ppm/° C. | 30 | 43 | 38 | 40 | 41 | 40 |
| storage modulus variation | % | 35 | 28 | 36 | 25 | 38 | 36 |
| rate | | | | | | | |
| microvoid grade | none | A | A | A | A | A | A |

TABLE 2
Resin compositions of Examples (in part by weight) and test results

| Component | | E7 | E8 | E9 | E10 | E11 | E12 |
|---|---|---|---|---|---|---|---|
| unsaturated C═C double | SA9000 | 100 | 100 | 100 | 100 | 100 | 100 |
| bond-containing | OPE-2st 1200 | | | | | | |
| polyphenylene ether resin | OPE-2st 2200 | | | | | | |
| compound of Formula (1) | Formula (1-1) | | | 45 | 25 | 10 | 5 |
| | Formula (1-2) | | | | | | |
| compound of Formula (2) | Formula (2-1) | 50 | | | | | |
| | Formula (2-2) | | 50 | 5 | 25 | 40 | 45 |
| oligomer of compound of | Formula (3-1) | | | | | | |
| Formula (2) | | | | | | | |
| benzocyclobutene-modified | P1 | 50 | 50 | 50 | 50 | 50 | 50 |
| polyolefin | P2 | | | | | | |
| | P3 | | | | | | |
| | P4 | | | | | | |
| | P5 | | | | | | |
| | P6 | | | | | | |
| | P7 | | | | | | |
| | P8 | | | | | | |
| | P9 | | | | | | |
| | P10 | | | | | | |
| Ricon 100 | | | | | | | |
| B-1000 | | | | | | | |
| B1 | | | | | | | |
| DVB | | | | | | | |
| TAIC | | | | | | | |
| C1 | | | | | | | |
| indane MI | | | | | | | |
| curing accelerator | 25B | 1 | 1 | 1 | 1 | 1 | 1 |
| inorganic filler | synthesized | 220 | 220 | 220 | 220 | 220 | 220 |
| | spherical silica | | | | | | |
| solvent | toluene:MEK = 2:1 | PA | PA | PA | PA | PA | PA |

| Item | Unit | E7 | E8 | E9 | E10 | E11 | E12 |
|---|---|---|---|---|---|---|---|
| post-plating P/S uniformity | lb/in | 0.25 | 0.22 | 0.32 | 0.29 | 0.26 | 0.23 |
| solder floating | % | 0 | 0 | 0 | 0 | 0 | 0 |
| delamination rate | | | | | | | |
| Z-CTE | ppm/° C. | 34 | 32 | 39 | 36 | 33 | 33 |
| storage modulus variation | % | 33 | 30 | 36 | 34 | 32 | 31 |
| rate | | | | | | | |
| microvoid grade | none | A | A | A | A | A | A |

TABLE 3
Resin compositions of Examples (in part by weight) and test results

| Component | | E13 | E14 | E15 | E16 | E17 | E18 |
|---|---|---|---|---|---|---|---|
| unsaturated C═C double | SA9000 | 100 | 100 | 100 | 100 | | |
| bond-containing | OPE-2st 1200 | | | | | 100 | |
| polyphenylene ether resin | OPE-2st 2200 | | | | | | 100 |
| compound of Formula (1) | Formula (1-1) | | | | | 30 | |
| | Formula (1-2) | | | | | | 30 |
| compound of Formula (2) | Formula (2-1) | | | | | 30 | |
| | Formula (2-2) | 50 | 50 | 50 | 50 | | 20 |
| oligomer of compound of | Formula (3-1) | | | | | | |
| Formula (2) | | | | | | | |
| benzocyclobutene-modified | P1 | 45 | 35 | 25 | 20 | | |
| polyolefin | P2 | | | | | | |
| | P3 | | | | | 15 | |
| | P4 | | | | | | 20 |
| | P5 | | | | | | 40 |
| | P6 | | | | | 15 | |
| | P7 | 5 | 15 | 25 | 30 | | |
| | P8 | | | | | | |
| | P9 | | | | | | |
| | P10 | | | | | | |
| Ricon 100 | | | | | | | |
| B-1000 | | | | | | | |
| B1 | | | | | | | |
| DVB | | | | | | | |
| TAIC | | | | | | | |
| C1 | | | | | | | |
| indane MI | | | | | | | |
| curing accelerator | 25B | 1 | 1 | 1 | 1 | 1 | 1 |
| inorganic filler | synthesized | 220 | 220 | 220 | 220 | 220 | 350 |
| | spherical silica | | | | | | |
| solvent | toluene:MEK = 2:1 | PA | PA | PA | PA | PA | PA |

| Item | Unit | E13 | E14 | E15 | E16 | E17 | E18 |
|---|---|---|---|---|---|---|---|
| post-plating P/S uniformity | lb/in | 0.18 | 0.15 | 0.12 | 0.07 | 0.20 | 0.16 |
| solder floating | % | 0 | 0 | 0 | 0 | 0 | 0 |
| delamination rate | | | | | | | |
| Z-CTE | ppm/° C. | 35 | 37 | 40 | 41 | 36 | 26 |
| storage modulus variation | % | 33 | 34 | 36 | 37 | 36 | 28 |
| rate | | | | | | | |
| microvoid grade | none | A | A | A | A | A | A |

TABLE 4
Resin compositions of Examples (in part by weight) and test results

| Component | | E19 | E20 | E21 | E22 | E23 |
|---|---|---|---|---|---|---|
| unsaturated C═C double bond- | SA9000 | 100 | 100 | 50 | 30 | 40 |
| containing polyphenylene ether | OPE-2st 1200 | | | 25 | 50 | 10 |
| resin | OPE-2st 2200 | | | 25 | 20 | 50 |
| compound of Formula (1) | Formula (1-1) | | | 10 | 20 | |
| | Formula (1-2) | 25 | 10 | 5 | 10 | 20 |
| compound of Formula (2) | Formula (2-1) | 15 | | 5 | 10 | 15 |
| | Formula (2-2) | | 10 | | 5 | 35 |
| oligomer of compound of Formula | Formula (3-1) | | | 5 | | 5 |
| (2) | | | | | | |
| benzocyclobutene-modified | P1 | | | 25 | 10 | 5 |
| polyolefin | P2 | 60 | 10 | 5 | 25 | 20 |
| | P3 | | | 5 | | |
| | P4 | | | 3 | 5 | |
| | P5 | | | 5 | | |
| | P6 | | 20 | | 5 | |
| | P7 | 20 | | 2 | | 5 |
| | P8 | | | | 3 | |
| | P9 | | | 1 | | |
| | P10 | | | | 2 | |
| Ricon 100 | | | | | | |
| B-1000 | | | | 5 | | |
| B1 | | | | | | |
| DVB | | | | | | |
| TAIC | | | | | | |
| C1 | | | | | 10 | |
| indane MI | | | | 5 | | 10 |
| curing accelerator | 25B | 1 | 2 | 1 | 0.5 | 1 |
| inorganic filler | synthesized spherical | 220 | 120 | 220 | 260 | 260 |
| | silica | | | | | |
| solvent | toluene:MEK = 2:1 | PA | PA | PA | PA | PA |

| Item | Unit | E19 | E20 | E21 | E22 | E23 |
|---|---|---|---|---|---|---|
| post-plating P/S uniformity | lb/in | 0.15 | 0.09 | 0.07 | 0.10 | 0.04 |
| solder floating delamination | % | 0 | 0 | 0 | 0 | 0 |
| rate | | | | | | |
| Z-CTE | ppm/° C. | 31 | 43 | 35 | 32 | 33 |
| storage modulus variation rate | % | 35 | 40 | 33 | 29 | 28 |
| microvoid grade | none | A | A | A | A | A |

TABLE 5
Resin compositions of Comparative Examples (in part by weight) and test results

| Component | | C1 | C2 | C3 | C4 | C5 | C6 |
|---|---|---|---|---|---|---|---|
| unsaturated C═C double bond- | SA9000 | 100 | 100 | 100 | 100 | 100 | 0 |
| containing polyphenylene | OPE-2st 1200 | | | | | | |
| ether resin | OPE-2st 2200 | | | | | | |
| compound of Formula (1) | Formula (1-1) | | | | 50 | | |
| | Formula (1-2) | | | | | | |
| compound of Formula (2) | Formula (2-1) | | | | | | |
| | Formula (2-2) | 0 | 120 | 50 | | 50 | 50 |
| oligomer of compound of | Formula (3-1) | | | | | | |
| Formula (2) | | | | | | | |
| benzocyclobutene-modified | P1 | 50 | 50 | 0 | 0 | 120 | 50 |
| polyolefin | P2 | | | | | | |
| | P3 | | | | | | |
| | P4 | | | | | | |
| | P5 | | | | | | |
| | P6 | | | | | | |
| | P7 | | | | | | |
| | P8 | | | | | | |
| | P9 | | | | | | |
| | P10 | | | | | | |
| Ricon 100 | | | | | | | |
| B-1000 | | | | | | | |
| B1 | | | | | | | |
| DVB | | | | | | | |
| TAIC | | | | | | | |
| C1 | | | | | | | |
| indane MI | | | | | | | |
| curing accelerator | 25B | 1 | 1 | 1 | 1 | 1 | 1 |
| inorganic filler | synthesized | 220 | 220 | 220 | 220 | 220 | 220 |
| | spherical silica | | | | | | |
| solvent | toluene:MEK = 2:1 | PA | PA | PA | PA | PA | PA |

| Item | Unit | C1 | C2 | C3 | C4 | C5 | C6 |
|---|---|---|---|---|---|---|---|
| post-plating P/S uniformity | lb/in | 0.45 | 0.40 | 0.42 | 0.47 | 0.41 | 0.55 |
| solder floating delamination | % | 20 | 15 | 42 | 56 | 12 | 100 |
| rate | | | | | | | |
| Z-CTE | ppm/° C. | 37 | 47 | 45 | 48 | 42 | 25 |
| storage modulus variation rate | % | 45 | 34 | 48 | 47 | 27 | 50 |
| microvoid grade | none | C | B | C | C | B | C |

TABLE 6
Resin compositions of Comparative Examples (in part by weight) and test results

| Component | | C7 | C8 | C9 | C10 | C11 |
|---|---|---|---|---|---|---|
| unsaturated C═C double bond- | SA9000 | 100 | 100 | 100 | 100 | 100 |
| containing polyphenylene ether resin | OPE-2st 1200 | | | | | |
| | OPE-2st 2200 | | | | | |
| compound of Formula (1) | Formula (1-1) | | | | | |
| | Formula (1-2) | | | | | |
| compound of Formula (2) | Formula (2-1) | | | | | |
| | Formula (2-2) | | | | 50 | 50 |
| oligomer of compound of Formula (2) | Formula (3-1) | | | | | |
| benzocyclobutene-modified polyolefin | P1 | 50 | 50 | 50 | | |
| | P2 | | | | | |
| | P3 | | | | | |
| | P4 | | | | | |
| | P5 | | | | | |
| | P6 | | | | | |
| | P7 | | | | | |
| | P8 | | | | | |
| | P9 | | | | | |
| | P10 | | | | | |
| Ricon 100 | | | | | 50 | |
| B-1000 | | | | | | 50 |
| B1 | | 50 | | | | |
| DVB | | | 50 | | | |
| TAIC | | | | 50 | | |
| C1 | | | | | | |
| indane MI | | | | | | |
| curing accelerator | 25B | 1 | 1 | 1 | 1 | 1 |
| inorganic filler | synthesized spherical | 220 | 220 | 220 | 220 | 220 |
| | silica | | | | | |
| solvent | toluene:MEK = 2:1 | PA | PA | PA | PA | PA |

| Item | Unit | C7 | C8 | C9 | C10 | C11 |
|---|---|---|---|---|---|---|
| post-plating P/S uniformity | lb/in | 0.41 | 0.41 | 0.46 | 0.40 | 0.49 |
| solder floating delamination rate | % | 11 | 18 | 21 | 23 | 25 |
| Z-CTE | ppm/° C. | 35 | 33 | 41 | 49 | 44 |
| storage modulus variation rate | % | 42 | 41 | 44 | 51 | 44 |
| microvoid grade | none | B | C | C | B | B |

For the property tests of Examples and Comparative Examples disclosed herein, samples (specimens) were prepared as described below and tested under specified conditions below.

### Preparation of Prepreg (PP)

Resin composition from each Example or each Comparative Example was individually well-mixed to form a varnish, which was then loaded to an impregnation tank; a fiberglass fabric (e.g., 2116 or 1078 L-glass fiber fabric, all available from Asahi) was impregnated into the impregnation tank to adhere the resin composition onto the fiberglass fabric, followed by heating at 130° C. to 160° C. to the B-stage to obtain a prepreg. Prepregs made from the 1078 L-glass fiber fabrics have a resin content of about 67%, and prepregs made from the 2116 L-glass fiber fabrics have a resin content of about 55%.

For Examples and Comparative Examples disclosed herein, test items and test methods are described below:

### 1. Post-Plating Copper Foil Peeling Strength (P/S) Uniformity

### (1) Preparation of Copper-Containing Inner Laminate I

Two 18 μm hyper very low profile (HVLP) copper foils and eight prepregs obtained from the resin composition in Example or Comparative Example and 2116 L-glass fiber fabrics were prepared and stacked in the order of one HVLP copper foil, eight prepregs and one HVLP copper foil, followed by lamination under vacuum at 500 psi and 210° C. for 2 hours to form the copper-containing inner laminate I.

### (2) Preparation of Evaluation Laminate I

Brown oxidation process was performed on both sides of the copper-containing inner laminate I, and then one prepreg obtained from the resin composition of Example or Comparative Example and 1078 L-glass fiber fabrics was separately stacked on both sides of the inner laminate treated by brown oxidation. Next, one 18 μm high temperature elongation (HTE) copper foil was separately stacked on the surface of the two prepregs, followed by lamination under vacuum at 500 psi and 210° C. for 2 hours to form a four-layer board, and then the four-layer board was electroplated until the thickness of the surface copper foil increased to 35 μm to form the evaluation laminate I.

### (3) Measurement of Post-Plating P/S Uniformity

Three 0.5 inch*5 inch strips were separately cut out from the peripheral area and the central area of the evaluation laminate I respectively. A tensile strength tester was used by reference to IPC-TM-650 2.4.8 at room temperature (about 25° C.) to measure the force (lb/in) required to separate the surface copper foil of each strip (having a thickness of 35 μm) from the surface of the insulation layer. The average force required to separate the surface copper foil of three strips (cut out from the central area) from the surface of the insulation layer was calculated as F1. The average force required to separate the surface copper foil of three strips (cut out from the peripheral area) from the surface of the insulation layer was calculated as F2. A difference in post-plating P/S between peripheral area and central area=absolute value of F1-F2, i.e., |F1-F2|. Smaller difference in post-plating P/S between peripheral area and central area represents better post-plating P/S uniformity.

### 2. Solder Floating Delamination Rate

### (1) Preparation of Copper-Free Inner Laminate II

Two 18 μm hyper very low profile (HVLP) copper foils and two prepregs obtained from the resin composition of Example or Comparative Example and 2116 L-glass fiber fabrics were prepared and stacked in the order of one HVLP copper foil, two prepregs and one HVLP copper foil, followed by lamination under vacuum at 500 psi and 210° C. for 2 hours to form a copper-containing inner laminate II, which was etched to remove the copper foils on both sides to obtain the copper-free inner laminate II.

### (2) Preparation of Evaluation Laminate II

Eight prepregs obtained from the resin composition of Example or Comparative Example and 1078 L-glass fiber fabrics and three aforesaid copper-free inner laminates II were prepared and stacked alternately in the order of one copper-free inner laminate II and two prepregs, and then one 18 μm HVLP copper foil was stacked on the front and back of the outermost layer respectively, followed by lamination under vacuum at 500 psi and 210° C. for 2 hours to form an eight-layer board, which was then drilled and electroplated to form the evaluation laminate II.

### (3) Measurement of Solder Floating Delamination Rate

The evaluation laminate II was cut into six pieces of 2.2 inch*5.9 inch sample. Each piece of sample was placed in a 288° C. solder bath for 10 seconds and then removed to cool down for 30 seconds, and this cycle was repeated for 20 times. The sample was then sliced and observed with an optical microscope to determine the presence or absence of delamination. Solder floating delamination rate=number of delamination holes*100%/total number of holes. Lower solder floating delamination rate is more preferred. As used herein, delamination may refer to interlayer separation or blistering. Delamination may occur between any layers of a laminate. For example, interlayer separation between insulation layers is considered as delamination; for example, blistering or separation between a copper foil and an insulation layer is also considered as delamination.

### 3. Z-Axis Coefficient of Thermal Expansion (Z-CTE)

The copper-containing inner laminate I was etched to remove the copper foils on both sides to obtain a copper-free inner laminate I sample, which was subjected to thermal mechanical analysis (TMA) by reference to IPC-TM-650 2.4.24.5. Each sample was heated from 50° C. to 260° C. at a temperature increase rate of 10° C./minute and then subjected to the measurement of Z-axis coefficient of thermal expansion (in ppm/° C.) in a temperature range of 50° C. to 260° C.

### 4. Storage Modulus Variation Rate

The copper-free inner laminate I sample was subjected to dynamic mechanical analysis (DMA) by reference to IPC-TM-650 2.4.24.4. Each sample was heated from 35° C. to 270° C. at a temperature increase rate of 2° C./minute. The storage modulus of each sample at 50° C. was recorded as X1, and the storage modulus of each sample at 250° C. was recorded as X2. Storage modulus variation rate=(X1−X2)/X1*100%. Lower storage modulus variation rate represents better heat resistance of an article.

### 5. Microvoid Grade

A section was made from the copper-free inner laminate I. The surface of the section was polished by argon ions, followed by focused ion beam microscopic processing and imaging technology, i.e., focused ion beam scanning electron microscopy (FIB-SEM) technology, to observe microvoids on the section surface at a magnification of 20,000×. If no microvoids (or voids) are observed within the field of view, Grade A is classified; if fewer than or equal to three microvoids are observed, Grade B is classified; and if more than three microvoids are observed, Grade C is classified. Grade A is considered the most ideal for microvoid grade.

The following observations can be made from the test results in Table 1 to Table 6.

From Examples E1 to E23, it can be confirmed that the resin composition of the present disclosure and an article made therefrom may achieve improvements in one or more properties including post-plating P/S uniformity, Z-CTE, storage modulus variation rate and microvoid grade.

The benzocyclobutene-modified polyolefin in the resin composition of Examples E1 to E12 includes only a benzocyclobutene-modified polyolefin not containing a heteroatom, and the benzocyclobutene-modified polyolefin in the resin composition of Examples E13 to E23 includes a combination of a benzocyclobutene-modified polyolefin containing a heteroatom and a benzocyclobutene-modified polyolefin not containing a heteroatom. If the resin composition contains at the same time both a benzocyclobutene-modified polyolefin containing a heteroatom and a benzocyclobutene-modified polyolefin not containing a heteroatom, in contrast to a resin composition only containing a benzocyclobutene-modified polyolefin not containing a heteroatom, the article made therefrom will achieve significant improvements in properties including post-plating P/S uniformity.

From the comparison of Examples E1 to E23 with Comparative Examples C1 and C2, it can be found that, relative to 100 parts by weight of the unsaturated C═C double bond-containing polyphenylene ether resin, if the amount of the component (B) is not within the range of 5 parts by weight to 100 parts by weight, the corresponding resin composition and the article made therefrom will have serious deterioration in at least two properties including post-plating P/S uniformity and microvoid grade.

From the comparison of Examples E1 to E23 with Comparative Examples C3, C4 and C5, it can be found that, relative to 100 parts by weight of the unsaturated C═C double bond-containing polyphenylene ether resin, if the amount of the component (C) is not within the range of 5 parts by weight to 100 parts by weight, the corresponding resin composition and the article made therefrom will have serious deterioration in at least two properties including post-plating P/S uniformity and microvoid grade.

From the comparison of Examples E1 to E23 with Comparative Examples C1, C3, C4 and C6, it can be found that if the resin composition does not at the same time contain the component (A), the component (B) and the component (C), the article made therefrom will have serious deterioration in at least several properties including post-plating P/S uniformity, storage modulus variation rate and microvoid grade.

From the comparison of Examples E1 to E23 with Comparative Examples C7 to C9, it can be found that if the component (B) of the present disclosure is used as a crosslinking agent, in contrast to using other crosslinking agents (such as the compound B1 or conventional crosslinking agents DVB and TAIC), the corresponding resin composition and the article made therefrom will achieve significant improvements in several properties including post-plating P/S uniformity, storage modulus variation rate and microvoid grade.

From the comparison of Examples E1 to E23 with Comparative Examples C10 and C11, it can be found that if the benzocyclobutene-modified polyolefin of the present disclosure is used, in contrast to using non-modified polyolefin (such as Ricon 100 or B-1000), the corresponding resin composition and the article made therefrom will achieve significant improvements in several properties including post-plating P/S uniformity, Z-CTE, storage modulus variation rate and microvoid grade.

The above detailed description and examples are merely illustrative in nature and are not intended to limit the embodiments of the subject matter or the applications and uses of such embodiments. As used herein, the term “exemplary” or similar expression means “serving as an example, instance, or illustration.” Any implementation described herein as exemplary is not necessarily to be construed as preferred or advantageous over other implementations, unless otherwise specified.

Moreover, while at least one exemplary example or comparative example has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description can provide those skilled in the art with a convenient guide for implementing the described one or more embodiments and equivalents thereof. Also, the scope defined by the claims includes known equivalents and foreseeable equivalents at the time of filing this patent application.

What is claimed is:

1. A resin composition, comprising:
(A) 100 parts by weight of an unsaturated C═C double bond-containing polyphenylene ether resin;
(B) 5 parts by weight to 100 parts by weight of a compound of Formula (1), a compound of Formula (2), an oligomer of the compound of Formula (1), an oligomer of the compound of Formula (2) or a combination thereof, and
(C) 5 parts by weight to 100 parts by weight of a benzocyclobutene-modified polyolefin; 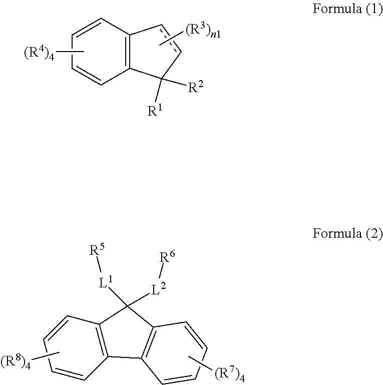
in Formula (1), R¹, R² and R³ are each independently selected from a hydrogen atom, a C₁ to C₅ alkyl group, a vinylphenyl group, a vinylbenzyl group, an allylphenyl group and an allylbenzyl group, and at least one of R¹, R² and R³ is a vinylphenyl group, a vinylbenzyl group, an allylphenyl group or an allylbenzyl group; R⁴ is each independently selected from a hydrogen atom and a C₁ to C₅ alkyl group; [symbol] represents a C—C single bond or a C═C double bond; when [symbol] represents a C—C single bond, n1 is 4, and when [symbol] represents a C═C double bond, n1 is 2;
in Formula (2), L¹ and L² are each independently selected from a C₁ to C₅ alkylene group and a C₆ to C₁₂ arylene group; R⁵ and R⁶ are each independently selected from a hydrogen atom, a C₁ to C₅ alkyl group, a vinylphenyl group, a vinylbenzyl group, an allylphenyl group and an allylbenzyl group, and at least one of R⁵ and R⁶ is a vinylphenyl group, a vinylbenzyl group, an allylphenyl group or an allylbenzyl group; and R⁷ and R⁸ are each independently selected from a hydrogen atom and a C₁ to C₅ alkyl group.

2. The resin composition of claim 1, comprising 5 parts by weight to 75 parts by weight of the compound of Formula (1), the compound of Formula (2), the oligomer of the compound of Formula (1), the oligomer of the compound of Formula (2) or a combination thereof.

3. The resin composition of claim 1, comprising 5 parts by weight to 80 parts by weight of the benzocyclobutene-modified polyolefin.

4. The resin composition of claim 1, wherein the unsaturated C═C double bond-containing polyphenylene ether resin comprises a vinylbenzyl group-containing polyphenylene ether resin, a (meth)acryloyl group-containing polyphenylene ether resin, a vinyl group-containing polyphenylene ether resin, an allyl group-containing polyphenylene ether resin or a combination thereof.

5. The resin composition of claim 1, wherein the compound of Formula (1) comprises a compound of Formula (1-1), a compound of Formula (1-2), a compound of Formula (1-3), a compound of Formula (1-4) or a combination thereof, and the compound of Formula (2) comprises a compound of Formula (2-1), a compound of Formula (2-2), a compound of Formula (2-3) or a combination thereof:

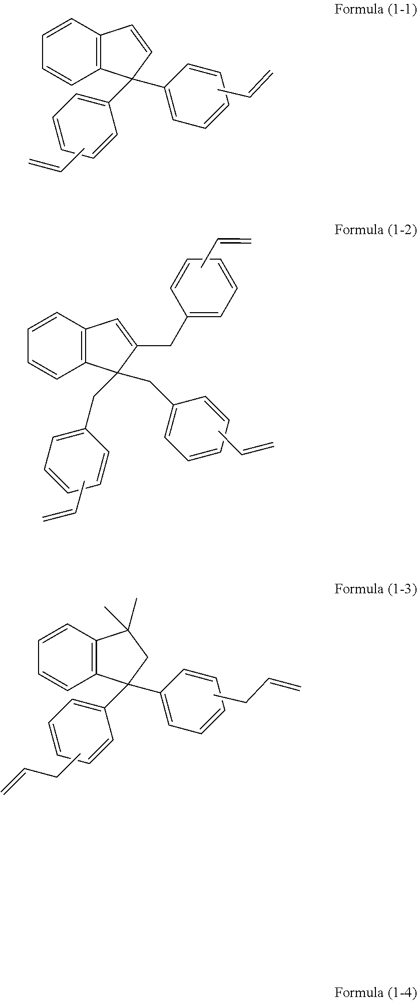

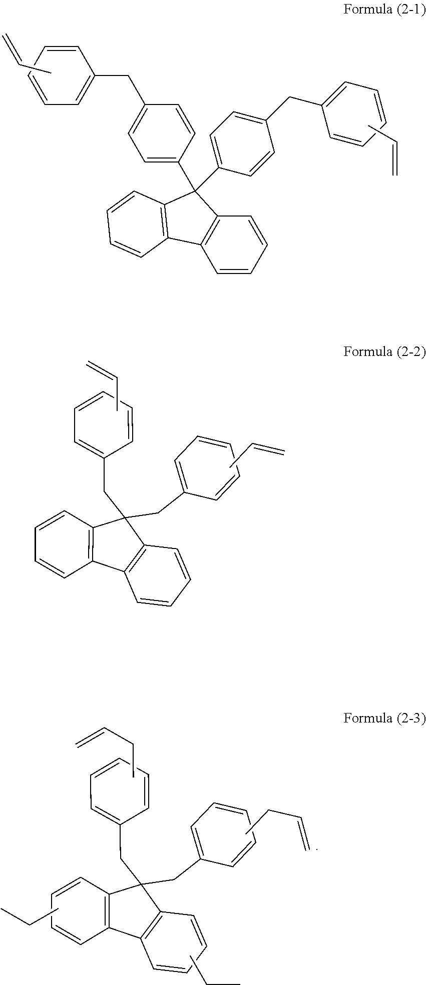

6. The resin composition of claim 1, wherein the benzocyclobutene-modified polyolefin comprises a benzocyclobutene-modified polyolefin containing a heteroatom, a benzocyclobutene-modified polyolefin not containing a heteroatom or a combination thereof.

7. The resin composition of claim 1, wherein the benzocyclobutene-modified polyolefin comprises a benzocyclobutene-modified polyolefin containing a heteroatom and a benzocyclobutene-modified polyolefin not containing a heteroatom at a weight ratio of 2:1 to 1:9.

8. The resin composition of claim 1, wherein the benzocyclobutene-modified polyolefin comprises a benzocyclobutene-modified polybutadiene, a benzocyclobutene-modified polyisoprene, a benzocyclobutene-modified product of styrene-butadiene copolymer, a benzocyclobutene-modified product of styrene-isoprene copolymer, a benzocyclobutene-modified product of styrene-butadiene-divinylbenzene polymer, a benzocyclobutene-modified product of styrene-ethylene-divinylbenzene polymer, a benzocyclobutene-modified product of styrene-ethylstyrene-divinylbenzene polymer, a benzocyclobutene-modified product of maleic anhydride-adducted polybutadiene, a benzocyclobutene-modified product of maleic anhydride-adducted polyisoprene, a benzocyclobutene-modified product of maleic anhydride-adducted styrene-butadiene copolymer, a benzocyclobutene-modified product of maleic anhydride-adducted styrene-isoprene copolymer, a benzocyclobutene-modified product of vinyl-polybutadiene-urethane polymer, a benzocyclobutene-modified product of silane-containing styrene-butadiene copolymer, a benzocyclobutene-modified product of acryloyl-terminated polybutadiene, a benzocyclobutene-modified product of epoxy-containing polybutadiene or a combination thereof.

9. The resin composition of claim 1, further comprising a polyolefin different from the benzocyclobutene-modified polyolefin, an organic silicone resin, a benzoxazine resin, an epoxy resin, a polyester resin, a phenol resin, an amine curing agent, a polyamide, a polyimide, a maleimide resin, a cyanate ester resin, a maleimide triazine resin or a combination thereof.

10. The resin composition of claim 1, further comprising curing accelerator, polymerization inhibitor, flame retardant, inorganic filler, surface treating agent, coloring agent, toughening agent, solvent or a combination thereof.

11. An article made from the resin composition of claim 1, comprising a prepreg, a resin film, a laminate or a printed circuit board.

12. The article of claim 11, which has one, more or all of the following properties:
a difference in post-plating copper foil peeling strength between peripheral area and central area as measured and calculated by reference to IPC-TM-650 2.4.8 of less than or equal to 0.34 lb/in;
a Z-axis coefficient of thermal expansion as measured by reference to IPC-TM-650 2.4.24.5 of less than or equal to 43 ppm/° C.; and
a storage modulus variation rate as measured and calculated by reference to IPC-TM-650 2.4.24.4 of less than or equal to 40%.
